(19) United States
(12) Patent Application Publication
(10) Pub. No.: US 2017/0092516 A1
(43) Pub. Date: Mar. 30, 2017

(54) MODULAR SYSTEM LAYOUT UTILIZING THREE-DIMENSIONS

(71) Applicant: Lam Research Corporation, Fremont, CA (US)

(72) Inventors: James Stephen van Gogh, Sunnyvale, CA (US); Mohsen Salek, Saratoga, CA (US); Candi Kristoffersen, San Jose, CA (US); Richard Howard Gould, Fremont, CA (US)

(21) Appl. No.: 15/276,260

(22) Filed: Sep. 26, 2016

Related U.S. Application Data
(60) Provisional application No. 62/235,352, filed on Sep. 30, 2015.

(51) Int. Cl. H01L 21/67; H01L 21/677

(52) U.S. Cl. CPC H01L 21/67173; H01L 21/67196; H01L 21/67733

(57) ABSTRACT

A semiconductor processing system may be provided that includes a first plurality of semiconductor processing tools with a first average wafer transfer plane and a second plurality of semiconductor processing tools with a second average wafer transfer plane. The second plurality of semiconductor processing tools may be vertically offset from the first plurality of semiconductor processing tools by a first vertical distance measured between the first average wafer transfer plane and the second average wafer transfer plane, and the first and second pluralities of semiconductor processing tools are in a commonly shared space.

### CROSS-REFERENCE TO RELATED APPLICATIONS

This application claims the benefit of U.S. Provisional Patent Application No. 62/235,352, filed Sep. 30, 2015, and titled “MODULAR SYSTEM LAYOUT UTILIZING 3-DIMENSIONS”, which is incorporated by reference herein in its entirety and for all purposes.

### BACKGROUND

Some semiconductor processing is performed in a facility called a Fabrication Plant in which semiconductor processing tools are arranged within a Fabrication Level according to a 2-dimensional layout. In some closely-packed layouts, the semiconductor processing tools may be separated by minimum distances that are required for service, maintenance, and/or electrical safety. Discussed herein are improvements relating to the layout of semiconductor processing tools in a Fabrication Plant.

### SUMMARY

In one embodiment, a semiconductor processing system may be provided. The semiconductor processing system may include a first plurality of semiconductor processing tools with a first average wafer transfer plane and a second plurality of semiconductor processing tools with a second average wafer transfer plane. The second plurality of semiconductor processing tools may be vertically offset from the first plurality of semiconductor processing tools by a first vertical distance measured between the first average wafer transfer plane and the second average wafer transfer plane and the first plurality of semiconductor processing tools and the second plurality of semiconductor tools may be in a commonly shared space.

In some embodiments, one or more building floors may not be between the first plurality of semiconductor processing tools and the second plurality of semiconductor processing tools.

In some embodiments, the commonly shared space may be a cleanroom.

In some embodiments, the commonly shared space may be a semiconductor fabrication room of a building.

In some embodiments, the semiconductor processing system may include a tool mounting architecture. The second plurality of semiconductor processing tools may be mounted in engagement with the tool mounting architecture.

In some such embodiments, the tool mounting architecture may be one or more of a suspension system, a floor, a wall, a ceiling, a frame, a catwalk, or a modular system.

In some embodiments, the first vertical distance may be less than about fifty feet.

In some embodiments, the second plurality of semiconductor processing tools may at least partially overlap the first plurality of semiconductor processing tools when viewed at a direction normal to the second average wafer transfer plane.

In some embodiments, the first average wafer transfer plane may include an x-axis and a y-axis normal to the x-axis and the second plurality of semiconductor processing tools may offset from the first plurality of semiconductor processing tools in a direction along of one or more of: the x-axis and the y-axis.

In some such embodiments, the second plurality of semiconductor processing tools may be offset from the first plurality of semiconductor processing tools by a first horizontal distance along the x-axis.

In some other such embodiments, the second plurality of semiconductor processing tools may be offset from the first plurality of semiconductor processing tools by a second horizontal distance along the y-axis.

In some embodiments, the semiconductor processing system may include a fabrication level with a floor and the first plurality of semiconductor processing tools may be arranged adjacent to the floor.

In some such embodiments, the semiconductor processing system may include an overhead hoist transportation system. Each semiconductor processing tool may include one or more interfaces that receives a container of wafers and the first plurality of semiconductor processing tools and second plurality of semiconductor processing tools may be arranged such that the overhead hoist transportation system can access the one or more interfaces that receives a container of wafers of the first plurality of semiconductor processing tools and the one or more interfaces that receives a container of wafers of second plurality of semiconductor processing tools.

In some other embodiments, the semiconductor processing system may include an intermediate fabrication level and the second plurality of semiconductor processing tools may be arranged in the intermediate fabrication level.

In some other embodiments, the semiconductor processing system may include a sub-fabrication level adjacent to the fabrication level. The one or more of the following may be at least partially located in the sub-fabrication level: storage and/or packaging for a gas box, a water manifold, a pneumatic manifold, or a high-voltage radiofrequency generator.

In some embodiments, the semiconductor processing system may include an air system and the air system may provide filtered air to the first plurality of semiconductor processing tools and the second plurality of semiconductor processing tools.

In some embodiments, the semiconductor processing system may include a third plurality of semiconductor processing tools with a third average wafer transfer plane. The third plurality of semiconductor processing tools may be vertically offset from the first plurality of semiconductor processing tools by a second vertical distance measured between the third average wafer transfer plane and the first average wafer transfer plane.

In some embodiments, each semiconductor processing tool may have one or more exclusion zones adjacent to the perimeter of that semiconductor processing tool, one or more of the exclusion zones of one semiconductor processing tool may be able to overlap with one or more exclusion zones of another other semiconductor processing tools, and the first plurality of semiconductor processing tools and the second plurality of semiconductor processing tools may be arranged such that during normal semiconductor processing operations the perimeter of at least one semiconductor processing tool does not encroach the one or more exclusion zones of at least one other semiconductor processing tool.

In some embodiments, the semiconductor processing system may include semiconductor processing facilities. The semiconductor processing facilities may include one or more of: storage and/or packaging for a gas box, a water manifold, a pneumatic manifold, a high-voltage radiofrequency generator, pipes, wires, cables, tubes, conduit, a pump, a power box, a chiller, and an abatement consolidation. At least one of the semiconductor processing tools in the first plurality of semiconductor processing tools may share one or more of the semiconductor processing facilities with at least one of the semiconductor processing tools from the second plurality of semiconductor processing tools.

In one embodiment, a semiconductor processing system may be provided. The semiconductor processing system may include a plurality of semiconductor processing tools, each of the plurality of semiconductor processing tools may have a horizontal extent and an average wafer transfer plane, and a tool mounting architecture in a commonly shared space. The plurality of tools may be mounted such that the horizontal extent of a first of the plurality of mounted tools overlaps the horizontal extent of a second of the plurality of mounted tools, and the average wafer transfer plane of the first of the plurality of mounted tools may be vertically offset from a second average wafer transfer plane of the second of the plurality of mounted tools.

In one embodiment, a semiconductor processing system may be provided. The semiconductor processing system may include a plurality of semiconductor processing tools, each of the plurality of semiconductor processing tools having a horizontal extent and an average wafer transfer plane; and a tool mounting architecture. The plurality of tools may be mounted such that the horizontal extent of a first of the plurality of mounted tools overlaps the horizontal extent of a second of the plurality of mounted tools, and the average wafer transfer plane of a first of the plurality of mounted tools may be vertically offset from a second average wafer transfer plane of a second of the plurality of mounted tools.

In one embodiment, a semiconductor processing system may be provided. The semiconductor processing system may include a Fabrication Level and a first plurality of semiconductor processing tools and a second plurality of semiconductor tools located in the Fabrication Level. Each semiconductor processing tool may include one or more processing chambers, one or more wafer transport systems, one or more wafer transfer planes, one or more interfaces for receiving a container of wafers, and an average wafer transfer plane. The first plurality of semiconductor processing tools may have a first average wafer transfer plane, the second plurality of semiconductor processing tools may have a second average wafer transfer plane, and the first plurality of semiconductor processing tools may be vertically offset from the second plurality of semiconductor processing tools by a first vertical distance measured between the first average wafer transfer plane and the second average wafer transfer plane.

In one embodiment, a semiconductor processing system may be provided. The semiconductor processing system may include a first plurality of semiconductor processing tools and a second plurality of semiconductor tools, each semiconductor processing tool including one or more processing chambers, one or more wafer transport systems, one or more wafer transfer planes, one or more interfaces for receiving a container of wafers, and an average wafer transfer plane. The first plurality of semiconductor processing tools may have a first average wafer transfer plane, the second plurality of semiconductor processing tools may have a second average wafer transfer plane, and the first plurality of semiconductor processing tools may be vertically offset from the second plurality of semiconductor processing tools by a first vertical distance measured between the first average wafer transfer plane and the second average wafer transfer plane.

In some embodiments, the first vertical distance may be less than about fifty feet.

In some embodiments, the first plurality of semiconductor processing tools and the second plurality of semiconductor tools may be in a commonly shared space.

In some such embodiments, the commonly shared space may be a Fab cleanroom.

In one embodiment, a semiconductor processing system may be provided. The semiconductor processing system may include a cleanroom and a first plurality of semiconductor processing tools and a second plurality of semiconductor tools located in the cleanroom. Each semiconductor processing tool may include one or more processing chambers, one or more wafer transport systems, one or more wafer transfer planes, one or more interfaces that receives a container of wafers, and an average wafer transfer plane. The first plurality of semiconductor processing tools may have a first average wafer transfer plane, the second plurality of semiconductor processing tools may have a second average wafer transfer plane, and the first plurality of semiconductor processing tools may be vertically offset from the second plurality of semiconductor processing tools by a first vertical distance measured between the first average wafer transfer plane and the second average wafer transfer plane.

In some embodiments, the first plurality of semiconductor processing tools may at least partially horizontally overlap the second plurality of semiconductor processing tools, and the first plurality of semiconductor processing tools may be horizontally offset from the second plurality of semiconductor processing tools.

In some such embodiments, the first plurality of semiconductor processing tools may be horizontally offset from the second plurality of semiconductor processing tools by a first horizontal distance.

In some other embodiments, the first plurality of semiconductor processing tools may not be substantially horizontally offset from the second plurality of semiconductor processing tools.

In some embodiments, the cleanroom may further include a fabrication level with a floor and the second plurality of semiconductor processing tools may be arranged adjacent to the floor.

In some such embodiments, the cleanroom may further include an overhead hoist transportation system, and the first plurality of semiconductor processing tools and second plurality of semiconductor processing tools may be arranged such that the overhead hoist transportation system can access the one or more interfaces that receives a container of wafers of the first plurality of semiconductor processing tools and second plurality of semiconductor processing tools.

In some embodiments, the cleanroom may further include a fabrication level, an intermediate fabrication level, and a sub-fabrication level adjacent to the fabrication level. The intermediate fabrication level may be interposed between the fabrication level and the sub-fabrication level.

In some embodiments, the cleanroom may further include a fabrication level and a sub-fabrication level adjacent to the fabrication level.

In some embodiments, the cleanroom may further include a ceiling, walls, and a plurality of levels.

In some embodiments, the cleanroom may further include an air system that may provide filtered air to the first plurality of semiconductor processing tools and the second plurality of semiconductor processing tools.

In some such embodiments, the cleanroom may further include a ceiling that includes the air system.

In some embodiments, the semiconductor processing system may include a third plurality of semiconductor processing tools that may have a third average wafer transfer plane and that may be vertically offset from the second plurality of semiconductor processing tools by a second vertical distance measured between the third average wafer transfer plane and the second average wafer transfer plane.

In some embodiments, the semiconductor processing system may include an air system that may provide filtered air to the first plurality of semiconductor processing tools and the second plurality of semiconductor processing tools.

In some embodiments, the semiconductor processing system may include a tool mounting architecture. The first plurality of semiconductor processing tools may be mounted in engagement with the tool mounting architecture.

In some such embodiments, the tool mounting architecture may be modular.

In some embodiments, each semiconductor processing tool may have one or more exclusion zones adjacent to the perimeter of the semiconductor processing tool, the one or more exclusion zones of one semiconductor processing tool may overlap with the one or more exclusion zones of one or more other semiconductor processing tools, and the first plurality of semiconductor processing tools and the second plurality of semiconductor processing tools may be arranged such that during normal semiconductor processing operations a semiconductor processing tool does not encroach the one or more exclusion zones of another semiconductor processing tool.

In some embodiments, the semiconductor processing system may include a plurality of semiconductor processing facilities and at least one of the semiconductor processing tools in the first plurality of semiconductor processing tools may share semiconductor facilities with at least one of the semiconductor processing tools from the second plurality of semiconductor processing tools.

In some embodiments, one or more building floors may not be between the first plurality of semiconductor processing tools and the second plurality of semiconductor processing tools.

In some embodiments, the semiconductor processing tools in the first plurality of semiconductor processing tools may be offset from each other by a second horizontal distance, and the semiconductor processing tools in the second plurality of semiconductor processing tools may be offset from each other by a third horizontal distance.

In some embodiments, one or more of semiconductor processing tools in the first plurality of semiconductor processing tools may be supported by one or more of the following: a suspension system, a floor, a wall, a ceiling, a frame, a catwalk, and a modular system.

In one embodiment, a semiconductor processing system may be provided. The semiconductor processing system may include a cleanroom and one or more elevated pluralities of semiconductor processing tools and a second plurality of semiconductor tools located in the cleanroom. Each semiconductor processing tool may include one or more processing chambers, one or more wafer transport systems, one or more wafer transfer planes, one or more interfaces that receives a container of wafers, and an average wafer transfer plane. Each of the one or more elevated plurality of semiconductor processing tools may have an average wafer transfer plane, the second plurality of semiconductor processing tools may have a second average wafer transfer plane, and each of the one or more elevated pluralities of semiconductor processing tools may be vertically offset from the second plurality of semiconductor processing tools by a vertical distance measured between the average wafer plane of each of the one or more elevated pluralities of semiconductor processing tools and the second average wafer transfer plane.

In some embodiments, the vertical distance for each of the one or more elevated pluralities of semiconductor processing tools may be substantially the same.

In some embodiments, two or more of the vertical distances for two or more of the one or more elevated pluralities of semiconductor processing tools may be different.

### BRIEF DESCRIPTION OF THE DRAWINGS

FIG. 1 depicts the top view of a simplified, demonstrative semiconductor processing tool.

FIG. 2 depicts an off-angle view of the semiconductor processing tool of FIG. 1.

FIG. 3 depicts a rear view of the semiconductor processing tool of FIG. 1 showing an example wafer transfer plane.

FIG. 4 depicts an off-angle view of the semiconductor processing tool of FIG. 1.

FIG. 5 depicts a rear view of a semiconductor processing tool similar to that of FIG. 3.

FIG. 6 depicts an example representation of a Fab Level, an Intermediate Level, and a Sub Fab Level of a Fab cleanroom.

FIG. 7 depicts a top view of a partial arrangement of semiconductor processing tools on a Fab Level.

FIGS. 8 and 9 depict two example layouts of semiconductor tools on a Fab Level.

FIG. 10 depicts a rear view of a representational example of a plurality of tools elevated above a plurality of tools located adjacent to, e.g., substantially on, a Fab Level floor.

FIG. 11 depicts top and rear views of an example dual level layout involving 16 tools.

FIGS. 12 and 13 depict off-angle views of the example dual layout of FIG. 11.

FIG. 14 depicts an isometric view of a partially exploded, partial dual layout of semiconductor processing tools in an example Fab.

FIG. 15 depicts a front view of the partially exploded, partial dual layout of semiconductor processing tools in the example Fab of FIG. 14.

FIG. 16 depicts top and rear views of another example dual level layout involving 16 tools.

FIG. 17 depicts a top view of yet another example dual level layout involving 16 tools.

FIG. 18 depicts a rear view of a representational example of two pluralities of tools elevated above a plurality of tools located adjacent to, e.g., substantially on, a Fab Level floor.

FIG. 19 depicts an off-angle view of an example structure supporting a semiconductor processing tool.

FIG. 20 depicts a top view of another example layout of semiconductor tools on a Fab Level.

FIG. 21 depicts a top view of yet another example layout of semiconductor tools on a Fab Level.

FIG. 22 depicts a top view of the example dual level layout similar to that of FIG. 11.

FIG. 23 depicts a top view of another example dual level layout on a Fab level.

### DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

There are many concepts and implementations described and illustrated herein. While certain features, attributes and advantages of the implementations discussed herein have been described and illustrated, it should be understood that many others, as well as different and/or similar implementations, features, attributes and advantages of the present disclosure, are apparent from the description and illustrations. As such, the below implementations are merely exemplary. They are not intended to be exhaustive or to limit the disclosure to the precise forms, techniques, materials and/or configurations disclosed. Many modifications and variations are possible in light of this disclosure. It is to be understood that other implementations may be utilized and operational changes may be made without departing from the scope of the present disclosure. As such, the scope of the disclosure is not limited solely to the description below because the description of the below implementations has been presented for the purposes of illustration and description.

Importantly, the present disclosure is neither limited to any single aspect nor implementation, nor to any single combination and/or permutation of such aspects and/or implementations. Moreover, each of the aspects of the present disclosure, and/or implementations thereof, may be employed alone or in combination with one or more of the other aspects and/or implementations thereof. For the sake of brevity, many of those permutations and combinations will not be discussed and/or illustrated separately herein.

Some semiconductor processing is performed in a facility called a Fabrication Plant (hereinafter “Fab”). Some typical Fabs may have one or more levels, rooms, and/or cleanrooms in which a plurality of semiconductor processing tools are placed. For purposes of this disclosure, it is understood that a semiconductor processing tool (which may be synonymously referred to as a “semiconductor processing tool”, “processing tool”, or “tool”) is configured to independently accept a container of a plurality of wafers, transfer one or more wafers to and from the container and within the tool, process the one or more wafers, and release and/or eject the container of one or more processed wafers. The tool may include one or more processing chambers, one or more wafer transport systems, one or more interfaces which may receive a container of wafers, and an average wafer transfer plane. A processing chamber may be any processing chamber or module in which a wafer or substrate can be processed, for instance by atomic layer deposition or atomic later etch.

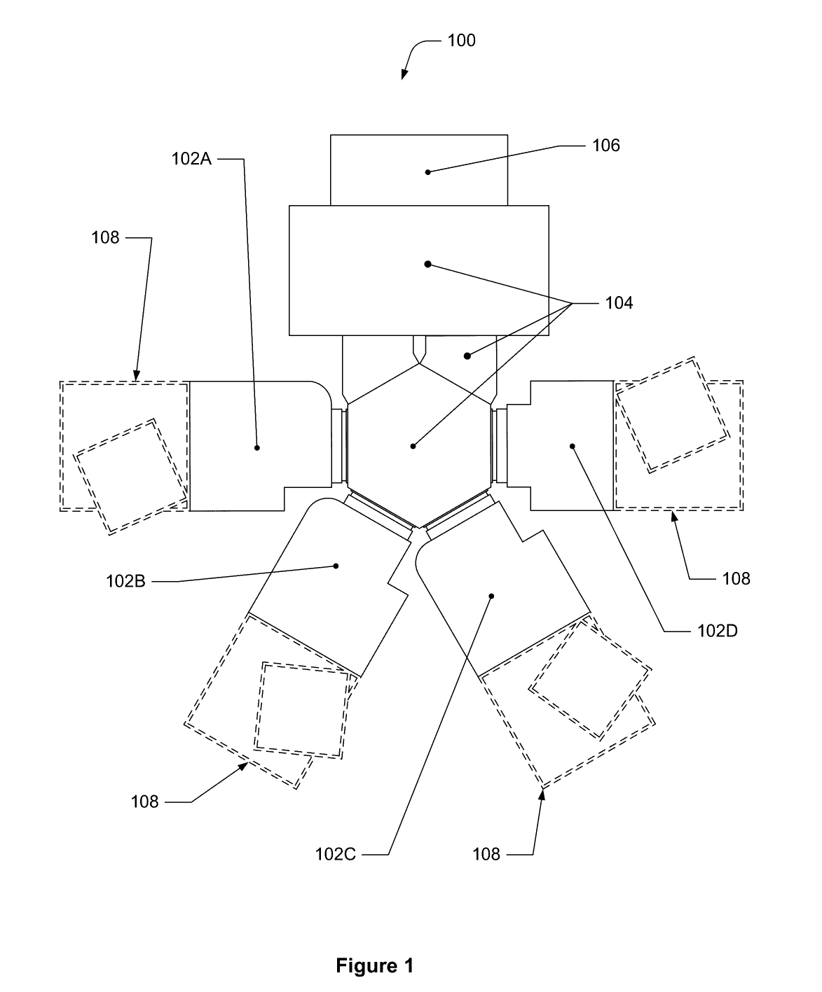

FIG. 1 depicts the top view of a simplified, demonstrative semiconductor processing tool. As can be seen, tool 100 includes four example processing chambers 102A-102D, example portions of the wafer transport system 104, an example interface which may receive wafers 106, and example exclusion zones 108 (discussed in greater detail) identified with dashed lines. In other figures included herein, the example exclusion zones may not be identified with dashed lines, and such elements are not a physical portion of the tool, but rather indicate the necessary service, maintenance, and/or electrical safety areas for the one or more portions of the tool, as discussed below.

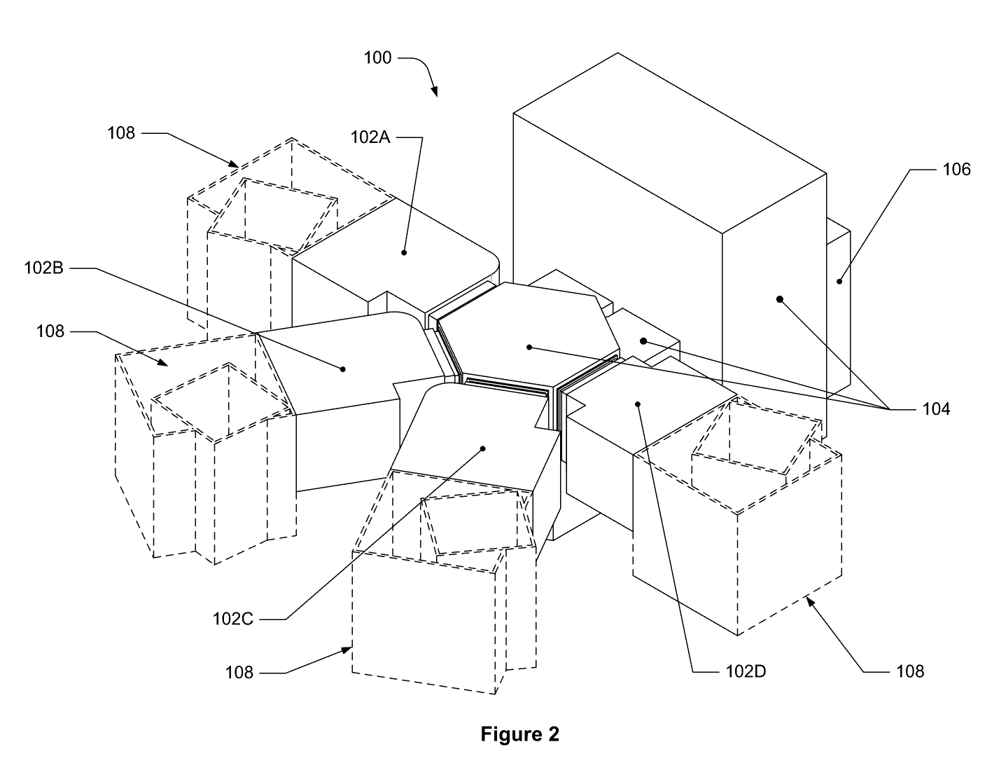

FIG. 2 depicts an off-angle view of the semiconductor processing tool of FIG. 1, with the same parts identified. Tools with a similar profile as tool 100 may be used within the figures herein, but such tools are not an exhaustive, limiting configuration of tools covered by this disclosure.

Each of the one or more processing chambers may include a substrate holder, such as a pedestal or chuck, and an interior volume which may be maintained under vacuum, gas delivery components configured to deliver (for example) film precursors, carrier and/or purge and/or process gases, secondary reactants, etc., and a showerhead, and equipment for generating a plasma within the processing chamber.

The one or more wafer transport systems 104 may include one or more robot arms that may have one or more end effectors configured to pick up and transport a wafer within the tool, including into and out of the one or more processing chambers, and/or move the wafer within and/or through the one or more wafer transfer planes. A tool may move the wafer within a specific plane of the tool, i.e., the wafer transfer plane, and a tool may have two or more wafer transfer planes. The one or more wafer transfer planes may reside within an actual or conceptual wafer transfer region (e.g. a three-dimensional space) within which the wafer is transferred within the tool.

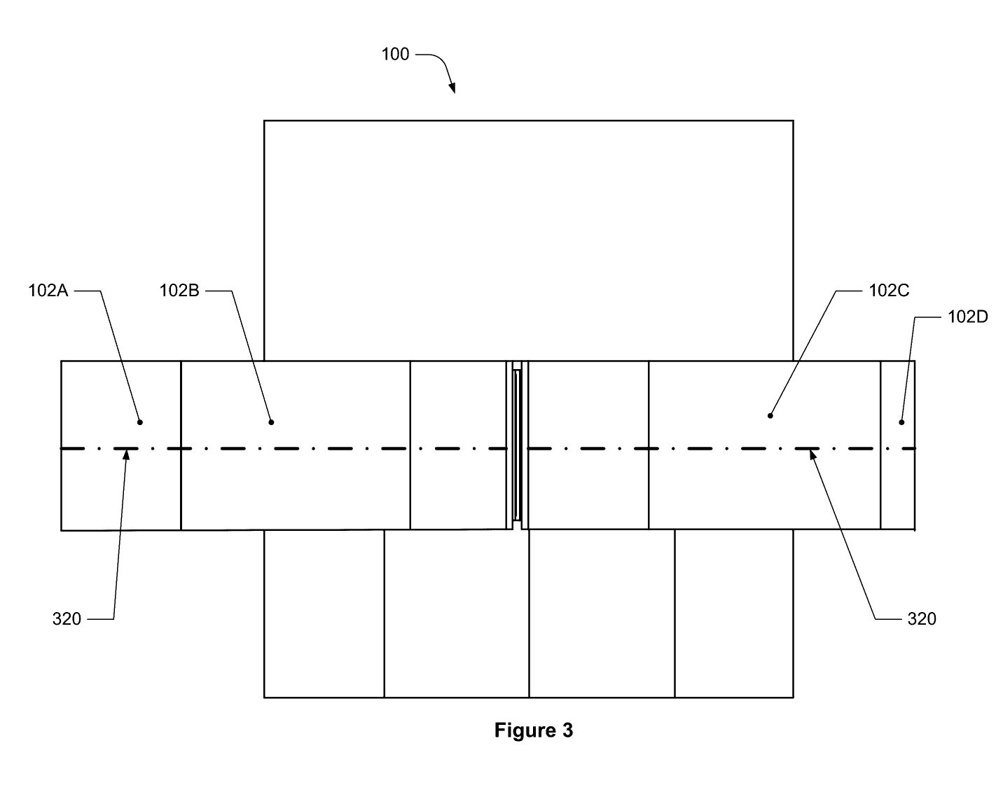

FIG. 3 depicts a rear view of the semiconductor processing tool of FIG. 1 showing an example wafer transfer plane. As can be seen, the semiconductor processing tool 100 includes a wafer transfer plane 320, identified as a dash-dot line. This single wafer transfer plane 320 may represent the plane, e.g., a single plane, in which the wafer is transported within tool 100, such as between the wafer transport system elements and one or more of the process chambers 102A-102D.

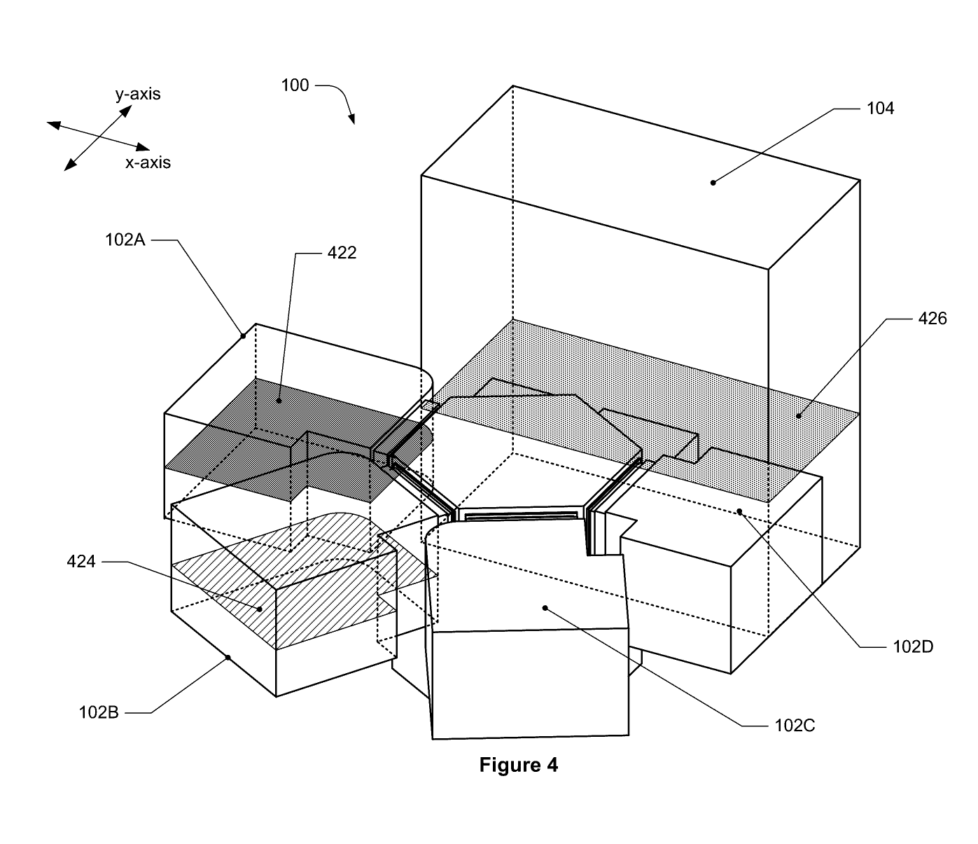

Another illustration of the wafer transfer planes in a semiconductor processing tool may be seen in FIG. 4 which depicts an off-angle view of the semiconductor processing tool of FIG. 1. Here, three sample wafer transfer planes within some parts of the semiconductor processing tool 100 can be seen. For instance, semiconductor processing tool 100 includes a first wafer transfer plane 422 in processing chamber 102A, a second wafer transfer plane 424 in processing chamber 102B, and a third wafer transfer plane 426 in a part of the wafer transport system 104. The hidden edges of items 102A, 102B, and 104 are depicted with dotted lines for further clarity. These three wafer transfer planes are not intended to be the only wafer transfer planes contained by the semiconductor processing tool 100, but rather are representative of possible wafer transfer planes within some aspects of the semiconductor processing tool 100. In some embodiments, the first, second, and third wafer transfer planes 422, 424, and 426, respectively, may all be in the same plane of the semiconductor processing tool 100 such that a wafer is moved throughout the semiconductor processing tool 100 only within a single plane in the tool that includes these three wafer transfer planes. These planes may therefore all be within the same wafer transfer plane 320 identified in FIG. 3. Accordingly, a wafer may be moved within the single wafer transfer plane of semiconductor processing tool 100 in the x- and y-directions.

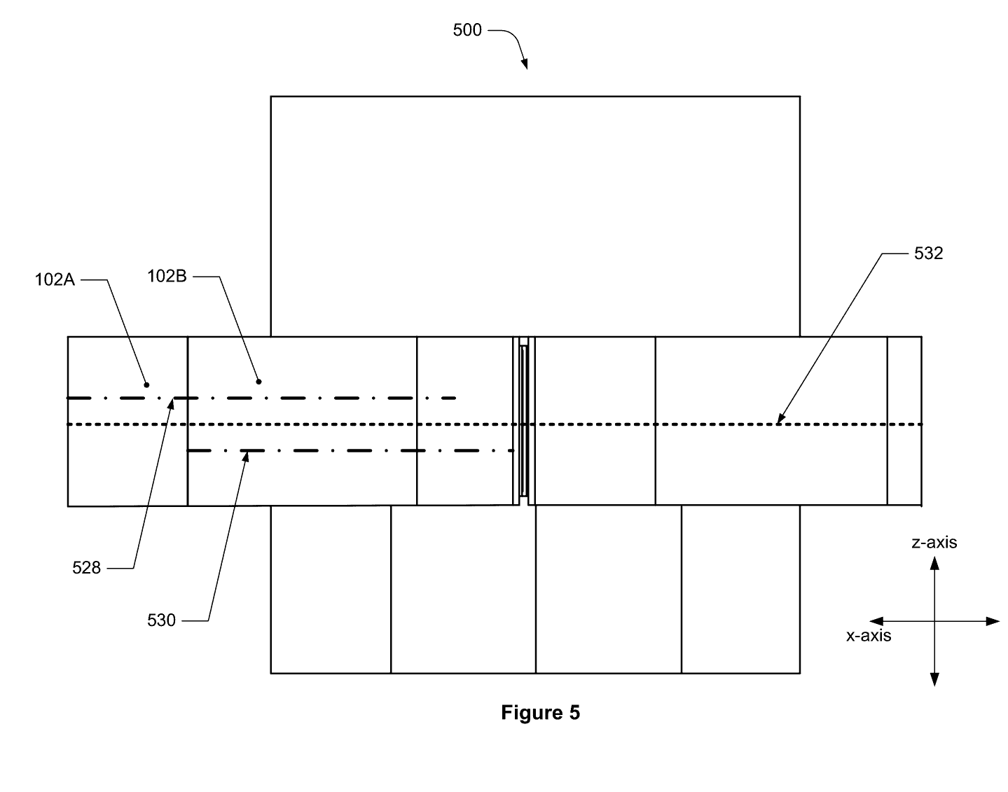

As noted above, in some embodiments, a semiconductor processing tool may have more than one wafer transfer plane. For instance, in some such embodiments, the first, second, and third wafer transfer planes 422, 424, and 426, respectively, of FIG. 4 may not all be in the same plane of the semiconductor processing tool 100. A further illustration of wafer transfer planes in a semiconductor processing tool may be seen in FIG. 5 which depicts a rear view of a semiconductor processing tool similar to that of FIG. 3. Here, the semiconductor processing tool 500 includes two separate wafer transfer planes 528 and 530. Similar to FIG. 4, these representative wafer transfer planes 528 and 530 are intended to be illustrative of multiple wafer transfer planes within a semiconductor processing tool and are not intended to be an exhaustive depiction of all wafer transfer planes within a semiconductor processing tool. Here, the two wafer transfer planes 528 and 530 are at different heights in the z-axis of the semiconductor processing tool 500 such that a wafer may be transported within the semiconductor processing tool 500 within and between at least these two wafer transfer planes 528 and 530. In some instances, this means that the wafer may be considered to move through a three-dimensional space within the semiconductor processing tool 500. Therefore, in such instances in which a tool has more than one wafer transfer plane, an average wafer transfer plane of that tool may be obtained which is a single plane that represents an average of all of the wafer transfer planes of that semiconductor processing tool, including any three-dimensional spaces in which a wafer is moved within the tool, which is identified as 532. This may be an average of the heights of a plane along a single axis, like along the z-axis of FIG. 5.

Referring back to FIGS. 1 and 2, the one or more interfaces which may receive a container of wafers 106 may be configured to receive a container of wafers. The container may be a cassette and/or Front Opening Unified Pod (“FOUP”) which may hold more than one wafer, for example 25 wafers. The semiconductor processing tool may also be configured to remove a wafer from the container of wafers and transport it into the one or more processing chambers 102A-102D for processing, as well as to load the container with one or more processed and/or partially processed wafers, for instance by the one or more wafer transport systems. The one or more interfaces which may receive a container of wafers 106 may also be configured to release and/or eject a wafer and/or a container of wafers from the tool. A semiconductor processing tool may be a vacuum semiconductor processing tool which operates below atmospheric pressure, and may also be semiconductor processing tool that operates at atmospheric pressure.

Some aspects of a Fab, including a Fab cleanroom, will now be discussed. A Fab cleanroom may include an enclosed space defined by a floor, walls and a ceiling, and may include a plurality of levels, including a Fab Level, and one or more of an Intermediate Level and a Sub Fab Level. The Fab cleanroom may also include an air flow level, which may be incorporated in a ceiling. Additionally, it is contemplated that a non-cleanroom environment in a Fab may also include the same such levels, elements, or a combination thereof. The discussion herein about a Fab cleanroom may also be applied to a non-cleanroom environment.

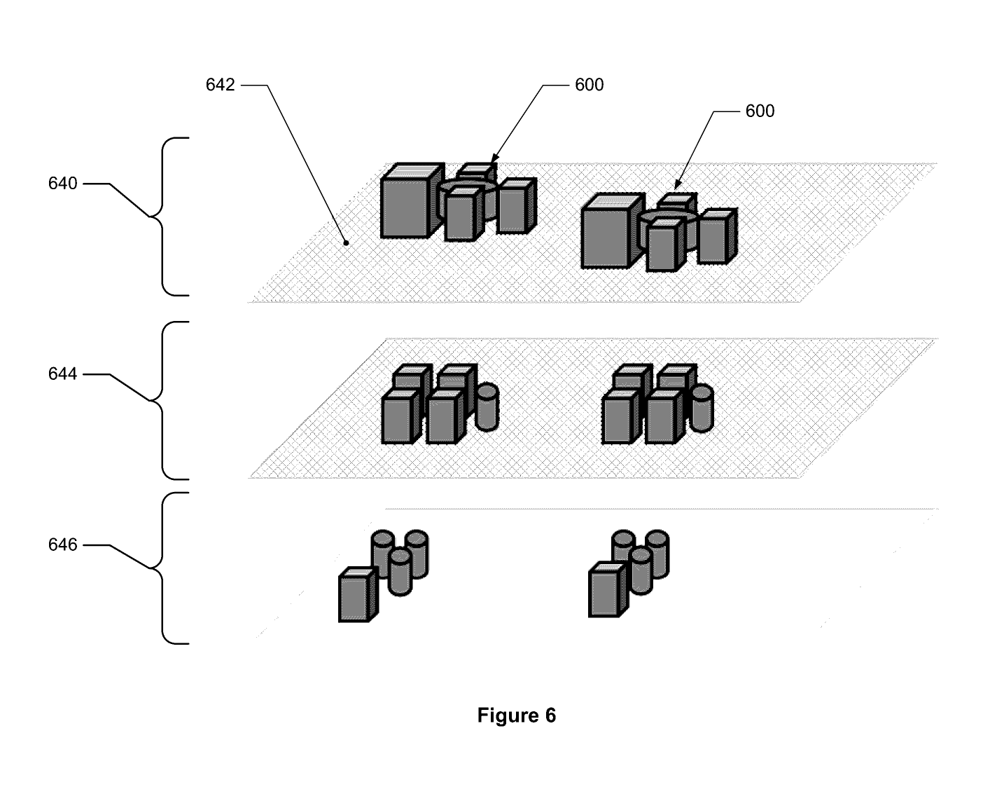

FIG. 6 depicts an example representation of a Fab Level, an Intermediate Level, and a Sub Fab Level of a Fab cleanroom. As can be seen in FIG. 6, the Fab Level 640 may include a floor 642 and a plurality of semiconductor processing tools 600 arranged along the Fab Level floor 642; example arrangements, or layouts, of these tools are discussed in more detail below. Some portions of a tool 600 may be directly supported by the Fab Level floor 642, while others may be indirectly supported by the Fab Level floor 642, some other portion of the Fab Level, such as the ceiling, or no portion of the Fab Level 640. For instance, a processing chamber may be supported by a power supply or other structure that may be placed directly on the Fab Level floor 642, while a wafer transport system may be supported directly by the Fab Level floor 642. Some tools may also be arranged such that they are adjacent to the Fab Level floor 642, meaning that such tools are considered “on” the Fab Level floor 642 even though some or all aspects of the semiconductor processing tool may be not physically located on or supported by the Fab Level floor 642. Additionally, as discussed herein, some aspects used by the tool may be located below the Fab Level 640 and/or Fab Level floor 642, such as a pump.

An “Intermediate Level” 644 may be located underneath the Fab Level 640 and may include facilities for use in semiconductor processing, such as storage and/or packaging for gas boxes, water manifolds, pneumatic manifolds, and/or high-voltage radiofrequency (“RF”) generators. The Intermediate Level 644 may have a perforated floor which allows pipes, wires, cables, tubes, and/or other conduit to run between the Intermediate Level 644 and the Fab Level 640. Some of the elements contained in the Intermediate Level 644 may be connected to one or more tools 600 on the Fab Level 640.

In some embodiments, as discussed below, an “intermediate level” may not include some or all of these facilities, but instead include a plurality of semiconductor processing tools.

A “Sub Fab Level” 646 may be placed underneath the Intermediate Level 644 and may contain equipment for use in semiconductor processing, such as pumps, power boxes, chillers, and/or abatement consolidation. The Sub Fab Level 646 may be constructed into a grid or honeycomb arrangement such that spaces or volumes may be created within the Sub Fab Level 646 to store equipment.

The ceiling of the Fab may include overhead lights as well as an air flow system that may provide filtered air, which may be a laminar air flow, into the Fab Level. The ceiling of the Fab and/or Fab Level may also include an Overhead Hoist Transportation system (“OHT”) which may be configured to transport containers of wafers to and from a tool, as discussed below. The Fab cleanroom may also be configured such that laminar air may flow from the Fab Level 640 to the Intermediate Level 644 and/or Sub Fab Level 646.

Some layouts of semiconductor processing tools on a Fab Level will now be discussed. Many layouts of tools on the Fab Level are made in two dimensional space, as viewed from a perspective substantially normal to the Fab Level floor, and such layouts may be based upon, among other things, an area taken up by each tool on the Fab Level, e.g. its foot print, as well as its exclusion zone which may include one or more service areas and/or one or more electrical clearance areas associated with the tool.

Referring back to FIGS. 1 and 2, exclusion zones 108 can be seen with the semiconductor processing tool 100. Such areas are not exhaustive depictions of all such areas of a tool, but rather are illustrative examples. The “service area” for a semiconductor processing tool may include the area that may be required to remove an element of a tool, perform maintenance on the element, add and/or replace parts onto the element of the tool, access the element, inspect the element, as well as for ergonomics and/or other industry standards for an element and/or tool. The “electrical clearance area” may include the clearance area required for the safety of persons and/or equipment, as well as the area required to prevent electrical interference between one or more elements of neighboring tools. The service and/or electrical areas may also include “working” service and/or electrical areas. Service and/or clearance areas for an element of a tool and/or tool may also be given by the publication “SEMI S8—Safety Guidelines for Ergonomics Engineering of Semiconductor Manufacturing Equipment”.

A tool may have multiple service areas and/or electrical clearance areas. As stated before, one or more service areas, one or more electrical areas, and/or a combination of one or more of these areas may be considered an “exclusion zone” for a tool and/or element of a tool. An exclusion zone for an element of a tool and/or a tool may exist in three dimensions, which may include one or more vertical dimensions (e.g., along the z-axis) in addition to horizontal dimensions (e.g., along the x- and y-axes). In some embodiments, all the exclusion zones for a tool may be combined into a single exclusion zone for the entire tool.

The tools on a Fab Level may be laid out in a variety of configurations. Some Fab Levels may be configured to have tool layouts that allow the highest number of tools to be placed on the Fab Level given at least some of the aforementioned constraints of the layouts, including, but not limited to, the area of the tools and the areas of the tools' corresponding service area(s), electrical clearance area(s), and/or exclusion zone(s). This concept may be referred to as the “packing density” of tools on a Fab Level.

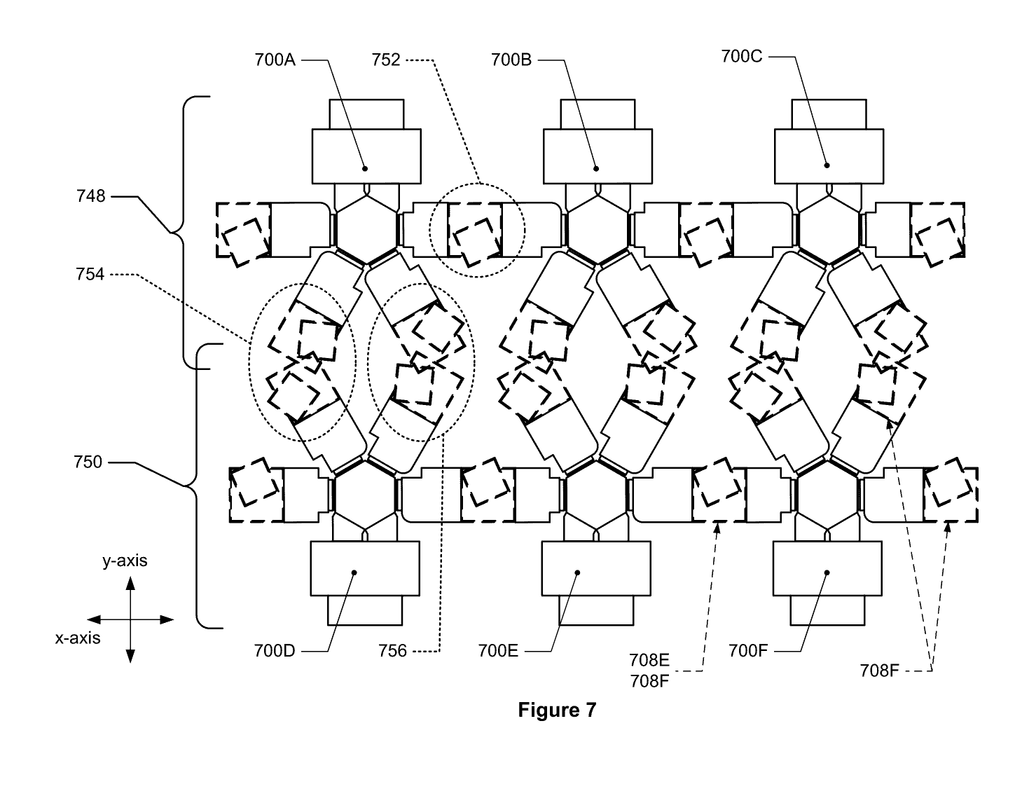

Tools are typically arranged such that packing density is maximized while enabling adequate, including minimum, clearance between tools in order to account for the exclusion zones. Accordingly, the packing density is limited by the exclusion zones of the tools. However, in some instances some or all of the exclusion zones of two or more tools may overlap, but the tools cannot be placed such that their physical elements enter, i.e., encroach, the exclusion zone of a neighboring tool. FIG. 7 depicts a top view of a partial arrangement of semiconductor processing tools on a Fab Level. Six semiconductor processing tools are seen, 700A-700F, respectively, with three tools 700A-700C in a first array 748 and three tools 700D-700F in a second array 750. The view of FIG. 7 is along the z-axis, with the tools arranged along the x- and y-axes. As can be seen, some of the exclusion zones, such as zones 708F for tool 700F, are overlapping between tools in the same array of tools as well as between tools in different arrays. For example, the exclusion zones of tools 700A and 700B are overlapping in the region identified in the dotted ellipse 752, while exclusion zones of tools 700A and 700D are also overlapping in the regions identified in the dotted ellipses 754 and 756. Additional and similar overlapping can be seen between other tools in FIG. 7. Accordingly, the tools in each array may be arranged along the x-axis such that at least some part, or all, of the exclusion zones for adjacent tools in the same array may overlap but the physical elements of the tools do not encroach into these exclusion zones. Such spacing may be made along the y-axis between tools in different arrays, such as exemplified between tools 700A and 700D. When a tool does not encroach an exclusion zone, it may mean that the perimeter of the tool, e.g., perimeter of the physical elements of the tool, may not encroach into the exclusion zone

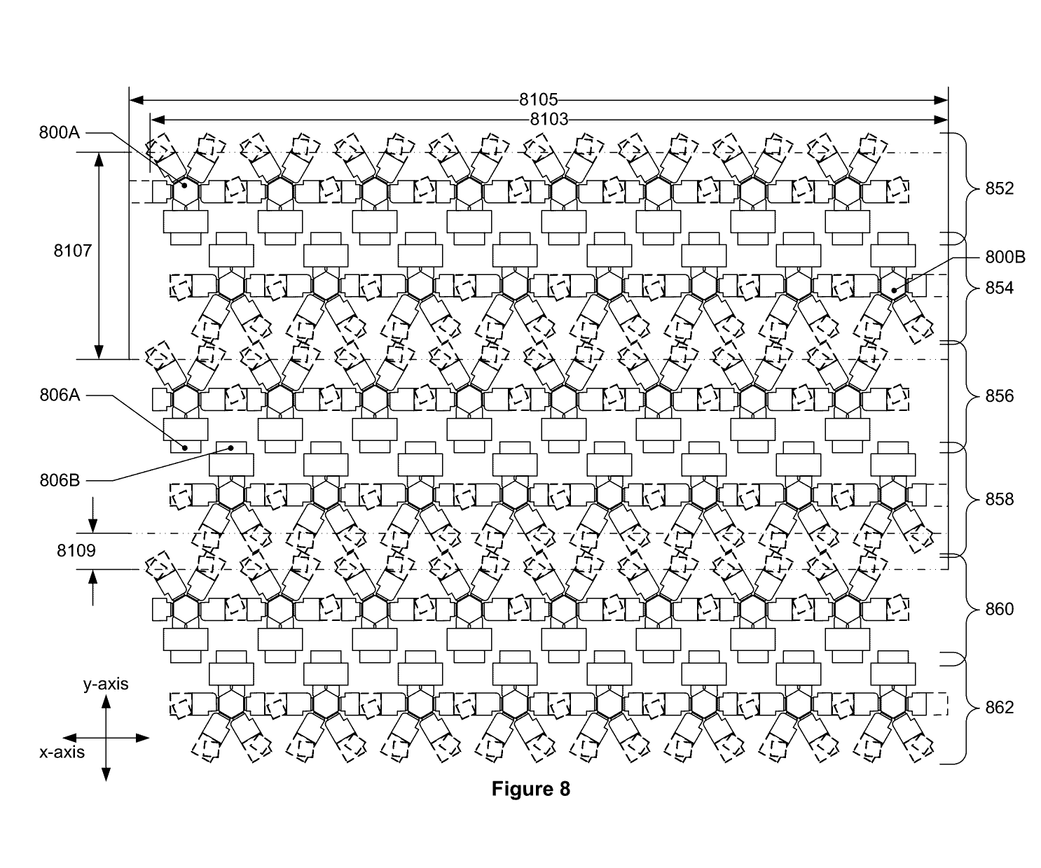

FIGS. 8 and 9 depict two example layouts of semiconductor tools on a Fab Level. In FIG. 8, the first example layout includes six rows of tools 852, 854, 856, 858, 860, and 862, e.g., six pluralities of tools, with each row having eight tools (not labeled). Similar to FIG. 7, each tool in a row has at least one exclusion zone that overlaps with an exclusion zone of an adjacent tool within that row. However, the rows of tools are arranged such that only some rows have overlapping exclusion zones with tools of other rows. For example, the exclusion zones of the tools of row 852 do not overlap with the exclusion zones of the tools of the adjacent row of tools 854, while at least one of the exclusion zones of each of the tools of row 854 do overlap with at least one of the exclusion zones of each of the tools of the adjacent row of tools 856. The rows of tools 852-862 are also arranged such that the interface which may receive wafers of each tool may be aligned with another row of tools such that two rows are “in-line”. For instance, as identified in FIG. 8, one tool in row 852 has the interface which may receive wafers 806A “in line” with the interface which may receive wafers 806B of a tool in row 854. This enables a single OHT system to easily access the interface which may receive wafers of tools that are in multiple rows.

FIG. 9 depicts a second example layout that includes four rows of tools 952, 954, 956, and 958, e.g., four pluralities of tools, with each row having eight tools (not labeled) resulting in a total of 32 total tools. Here, like in FIG. 8, each tool in a row has at least one exclusion zone that overlaps with an exclusion zone of an adjacent tool within that row. Unlike FIG. 8, the rows of tools of FIG. 9 are spaced apart from the other rows such that a gap exists between the interfaces which may receive wafers of the tools in adjacent rows. For instance, separation distance 963 exists between the interfaces which may receive wafers of the tools in rows 952 and 954. This separation distance 963 allows access to aspects of each tool, such as for service, processing, electrical clearance, safety, and/or maintenance. Similar to FIG. 8, at least one of the exclusion zones of each of the tools of row 954 do overlap with at least one of the exclusion zones of each of the tools of the adjacent row of tools 956.

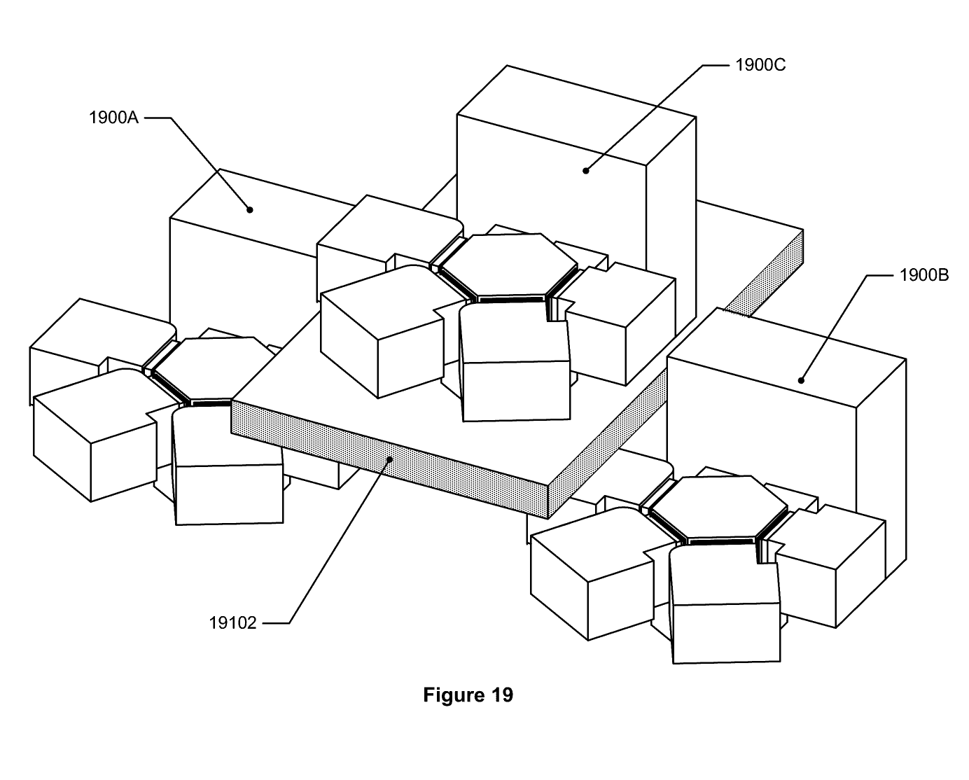

In some embodiments, the tools may be arranged along a Fab floor by various distances. FIG. 20 depicts a top view of another example layout of semiconductor tools on a Fab Level. As can be seen in FIG. 20, a plurality of eight semiconductor processing tools 2052 are in-line with each other and spaced apart from an adjacent tool by distance 20101. In some embodiments, this distance 20101 may be about 36 inches. A first length 20103 of the plurality of tools 2052 may be considered the length between an outer edge of a physical component of one of the tools on an end of the plurality of tools 2052, such as seen on the left hand side of FIG. 20, and an outer edge of an exclusion zone of a tool on the other end of the plurality of tools 2052, such as seen on the right hand side of FIG. 20. In some embodiments, this length 20103 may be about 1,177.9 inches (e.g., about 29,919 millimeters). A second length 20105 of the plurality of tools 2052 may be considered the length between an outer edge of an outer exclusion zone on one tool on the end of the plurality of tools 2052 and an outer edge of an outer exclusion zone on one tool on the other end of the plurality of tools 2052, as can be seen on the right and side of FIG. 20. In some embodiments this length 20105 may be about 1,213.9 inches (e.g., about 30,834 millimeters). The width 20107 of the plurality of tools may be measured between two physical components of the tools within the plurality of tools, as seen in FIG. 20. The width may also be measured between a physical component of a tool and an edge of an exclusion zone. In some embodiments, the width 20107 may be about 147.7 inches (e.g., about 3,752 millimeters)

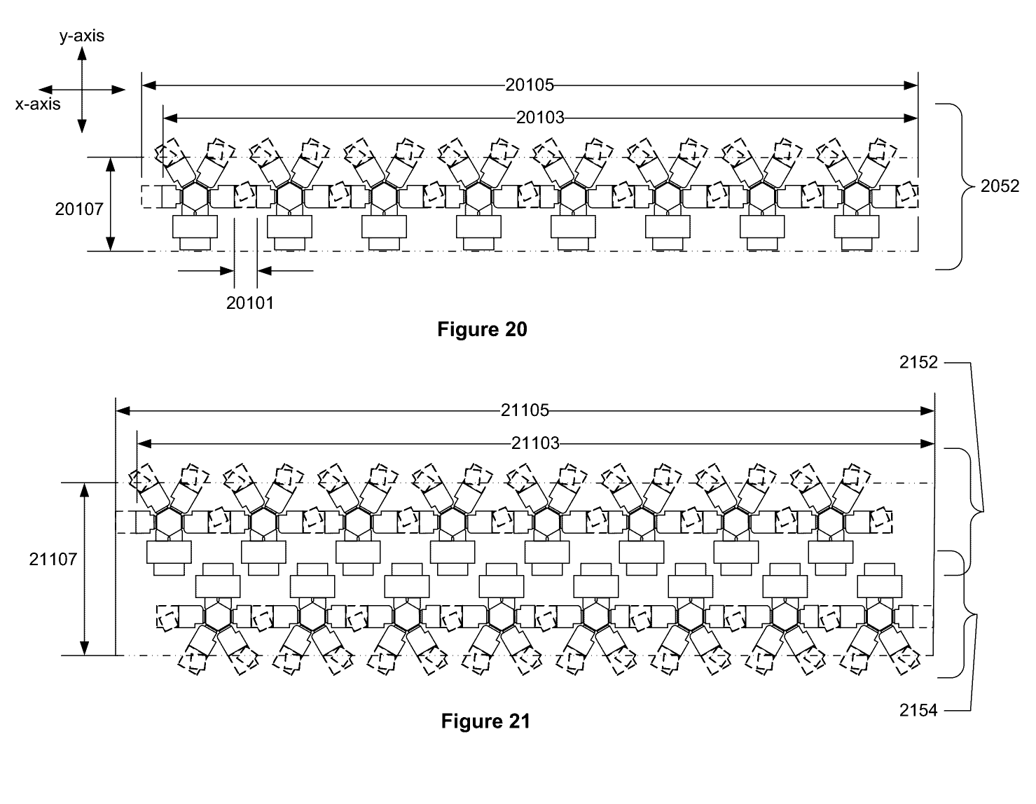

FIG. 21 depicts a top view of yet another example layout of semiconductor tools on a Fab Level. Similar to FIGS. 8 and 9, FIG. 21 includes two pluralities of eight semiconductor tools 2152 and 2154, respectively, that are placed in-line with each other like in FIG. 8. A first length 21103 of these two plurality of tools, may be considered the distance between an outer edge of a physical component of one of the tools on an end of the plurality of tools 2152, such as seen on the left side of FIG. 21, and an outer edge of an exclusion zone of a tool in the other plurality of tools 2154 that is on the opposite end of the plurality of tools 2154 (e.g., farthest from the one of the tools on an end of the plurality of tools 2152), such as seen on the right hand side of FIG. 21. A second length 21105 may be considered the distance between an outer edge of an exclusion zone of one of the tools on an end of the plurality of tools 2152, such as seen on the left hand edge of FIG. 21, and an outer edge of an exclusion zone of a tool in the other plurality of tools 2154 that is on the opposite end of the plurality of tools 2154 (e.g., farthest from the one of the tools on an end of the plurality of tools 2152), such as seen on the right hand side of FIG. 21. The total width 21107 of the two pluralities of tools may be measured between an outer edge of a physical component of one of the tools within one plurality of tools 2152 and an outer edge of a physical component of one of the tools within the other plurality of tools 2154, as seen in FIG. 21. The width 21107 may also be measured between a physical component of a tool and an edge of an exclusion zone. In some embodiments, the first length 21103 may be about 1,246.5 inches (e.g., about 31,660 millimeters), the second length 21105 may be about 1,282.5 inches (e.g., about 32,574 millimeters), and the width 21107 may be about 266.8 inches (e.g., about 6,777 millimeters).

Referring back to FIG. 8, the semiconductor tools may also be arranged by varying distances. Similar to FIG. 21, the pluralities of tools 852 and 854 together have a first length 8103 that may be considered the distance between an outer edge of a physical component of one of the tools, e.g., 800A, on an end of the plurality of tools 852, such as seen with the left hand edge in FIG. 8, and an outer edge of a exclusion zone of a tool, e.g., 800B, in the other plurality of tools 854 that is on the opposite end of the plurality of tools 854 (e.g., farthest from tool 800A), such seen in the right hand side of FIG. 8. A second length may be considered the distance between an outer edge of a physical component of tool 800A, such as seen with the left hand edge in FIG. 8, and an outer edge of a physical component of tool 800B in the other plurality of tools 854 that is on the opposite end of the plurality of tools 2154, such seen in the right hand side of FIG. 8. The total width 8107 of the two pluralities of tools may be measured between an outer edge of a physical component of one of the tools within one plurality of tools 852, e.g., tool 800A, and an outer edge of a physical component of one of the tools within the other plurality of tools 2154, e.g., 800B, as seen in FIG. 21.

As seen further in FIG. 8, the spacing between two pluralities of tools that are not in-line with each, e.g., pluralities of tools 858 and 860, respectively, may also be a spacing distance 8109. This distance may be measured between a physical component between of a tool in one plurality of tools and a physical component of a tool in the other plurality of tools, as seen in FIG. 8. In some embodiments, this spacing distance may be about 55 inches (e.g., 1,397 millimeters) or about 41 inches (e.g., about 1,041 millimeters).

Similarly, measurements between tools in FIG. 9 can also be seen. The spacing and distances may be the same as discussed above with respect to FIG. 20, such as, for instance first length 20103 may be considered the same as first length 9103, second length 20105 may be considered the same as second length 9105. The same discussion of FIG. 20 is incorporated herein. In some embodiments, the separation distance 963 between pluralities of tools 952 and 954, for instance, may be about 55 inches (e.g., 1,397 millimeters) or about 566 inches (e.g., 1,436 millimeters). This may be the spacing between the interfaces configured to receive a container of wafer. Additional spacing between other pluralities of tools, such as between adjacent pluralities of tools 954 and 956, e.g., spacing distance 9109, may be similar to spacing distance 8109 of FIG. 8 discussed above. As can also be seen in FIG. 9, there may be measured spacing between the two center pluralities of tools 954 and 956, and an adjacent plurality of tools, such as plurality of tools 958. This other separation distance 9111 may be measured between one physical component or edge of a tool in one of the two center pluralities of tools, 954 and 956, and a physical component of the adjacent plurality of tools, 958, as seen in FIG. 9. In some embodiments, this other separation distance 9111 may be about 391.4 inches (e.g., 9,943 millimeters) or about 374.5 inches (e.g., 9,512 millimeters).

The spacing described herein may be based on the factors also described above, such as the spacing required to remove one or more components of a semiconductor processing tool.

The present inventors have determined improvements for the layout of semiconductor processing tools within a Fab by using a 3-dimensional layout. In some configurations, a first plurality of semiconductor processing tools in a Fab Level and/or Fab cleanroom are vertically offset, i.e. elevated above, a second plurality of semiconductor processing tools that may be adjacent to the Fab Level floor. Some such configurations may be considered “multi-level” or 3-dimensional layouts because the tools are arranged on a Fab level according to a 2-dimensional layout, such as those described above, as well as spaced in the vertical direction. In other words, the 2-dimensional layouts along the Fab Level may be considered spaced along the x- and y-axes (e.g., like in FIGS. 7-9) and the multi-level, 3-dimensional layout utilizes the x-, y-, and z-axes. As discussed above, many typical Fab Levels have their tools arranged according to a 2-dimensional layout, but some Fab Levels and/or Fab cleanrooms have additional, un-used space above the Fab Level floor and within the Fab Level and/or Fab cleanroom where the first, elevated plurality of semiconductor processing tools may be placed.

Embodiments of a 3-dimensional layout may include one or more pluralities of tools elevated above a plurality of tools located adjacent to, e.g., substantially on, the Fab Level floor. In some embodiments, two or more pluralities of tools may be elevated above a plurality of tools located adjacent to the Fab Level floor by the same and/or different distances. For example, in some such embodiments, there may be three levels of tools within one Fab Level (e.g. vertical levels or layers), with a first plurality of tools located adjacent to the Fab Level floor, a second plurality of tools vertically offset from the first plurality of tools at a first distance, and a third plurality of tools vertically offset from the first plurality of tools at a second distance, in which the first and second distance are different.

Some other embodiments of a 3-dimensional layout may include one plurality of tools elevated above another plurality of tools located adjacent to, i.e., on, the Fab Level floor. As stated above, some tools may have one or more components directly supported by the Fab Level floor, while some other components may be indirectly or not supported by the Fab Level floor. These types of tools may be considered located substantially on and/or adjacent to the Fab Level floor. Such embodiments may be considered a “dual level” layout. For simplicity in this disclosure, examples of a dual level layout are described, but such examples, configurations, and/or embodiments may be applied to and considered for multi-level layouts.

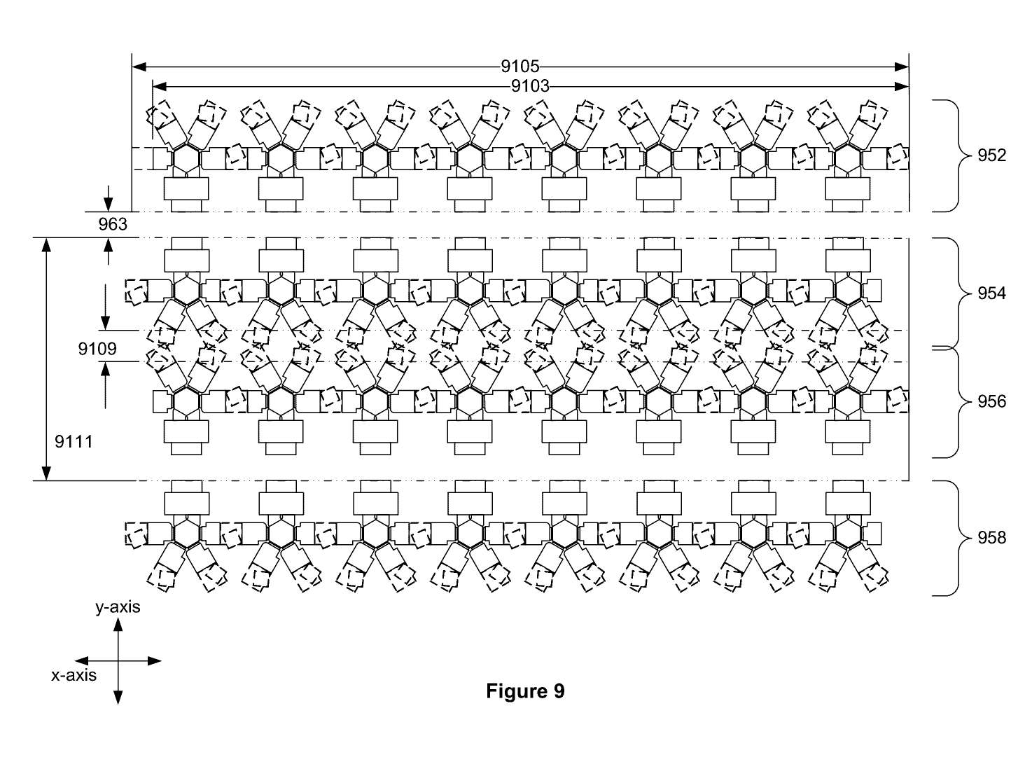

FIG. 10 depicts a rear view of a representational example of a plurality of tools elevated above a plurality of tools located adjacent to, e.g., substantially on, a Fab Level floor. FIG. 10 includes five semiconductor processing tools, with three tools in a first plurality of tools 1064 that are located adjacent to, i.e., on, a Fab Level floor 1068, and two tools in a second plurality of tools 1066. Each of the tools in FIG. 10 is similar or identical to the tools discussed above with respect to FIGS. 1-5 and FIG. 10 is shown from the same perspective as FIGS. 3-5, i.e., as a “rear view” viewed along the y-axis. For additional clarity, the exclusion zones of the tools in FIG. 10 are not depicted. As can be seen, the second plurality of tools 1066 are elevated above, e.g., vertically offset along the z-axis, from the first plurality of tools 1064. For illustrative purposes, the structure(s) supporting the second plurality of tools 1066 above the first plurality of tools 1064 has been omitted but such structure(s) is discussed below.

The vertical distance which may separate the first plurality of tools 1064 from the second plurality of tools 1066 may be determined using the distance between the average wafer transfer plane 1072 of the first plurality of tools 1064 and the average wafer transfer plane 1074 of the second plurality of tools 1066. Such measurement may be made at an angle substantially normal (e.g., within about +/−5 degrees of normal) to the average wafer transfer planes of the pluralities of tools, 1072 and 1074, respectively. As can be seen in FIG. 10, vertical distance 1070 is the separation distance between the average wafer transfer plane 1072 of the first plurality of tools 1064 and the average wafer transfer plane 1074 of the second plurality of tools 1066. This vertical distance may be considered the distance along the z-axis, i.e., in the z-direction.

As discussed above, in some embodiments the tools within a plurality of tools may have substantially the same average wafer transfer plane, e.g. +/−5 degrees, such that the average wafer transfer plane of the plurality of tools may be the same as the tools within that plurality. In other embodiments, the tools within a plurality of tools may have different average wafer transfer planes. In some such embodiments, the average wafer transfer planes of each of the tools within the plurality of tools are averaged to obtain a single average wafer transfer plane for the plurality of tools. In some such embodiments, as discussed above, the average wafer transfer plane for each tool may be obtained by averaging all the transfer planes within the tool.

In some other embodiments, the vertical distance which may separate the first plurality of tools from the second plurality of tools may be determined using the distance between the average wafer transfer plane of one or more tools within the first plurality of tools and the average wafer transfer plane of one or more tools within the second plurality of tools. In yet some other embodiments, this vertical distance may be determined using the distance between the average wafer transfer plane of one or more tools within the first plurality of tools or the average wafer transfer plane of the first plurality of tools, and the average wafer transfer plane of one or more tools within the second plurality of tools or the average wafer transfer plane of the second plurality of tools.

In some other embodiments, the vertical distance which may separate the first plurality of tools from the second plurality of tools may be determined using the distance between a portion of the structure supporting the second plurality of tools and the Fab Level floor. For example, some of the elements of the tools within the second plurality of tools may be placed adjacent to and/or directly or indirectly supported by the structure, while some of the elements of the tools within the first plurality of tools may be placed adjacent to and/or directly or indirectly supported by the Fab Level floor. In such an example, the vertical distance is between a portion of the structure and the Fab Level floor. For example, the structure may be a floor supporting the second plurality of tools and the vertical distance may be a distance between the floors.

In some embodiments, the vertical distance separating the first plurality of tools from the second plurality of tools may be more than three feet but less than or equal to forty feet. In some embodiments, there may be vertical overlap between one or more tools in the first plurality of tools and one or more tools in the plurality of second tools, but no such overlap between the average wafer transfer plane of the first plurality of tools and the second plurality of tools.

This vertical distance, as well as other aspects of the dual level layout, may be based on one or more factors, including, but not limited to, the available space in a cleanroom and/or Fab Level (e.g. between the Fab Level ceiling and floor), the facilities and parts for each tool, the exclusion zones, the service/maintenance areas, the electrical clearance areas, ergonomics, and/or SEMI S8—Safety Guidelines for Ergonomics Engineering of Semiconductor Manufacturing Equipment. For example, some two-dimensional service/maintenance considerations for a dual level layout may include height differences between front end module and/or gas box heights, delivery by the OHT systems to each of the plurality of tools, and the routing of facilities (e.g., gas and power lines) around tools in the top and bottom pluralities of tools.

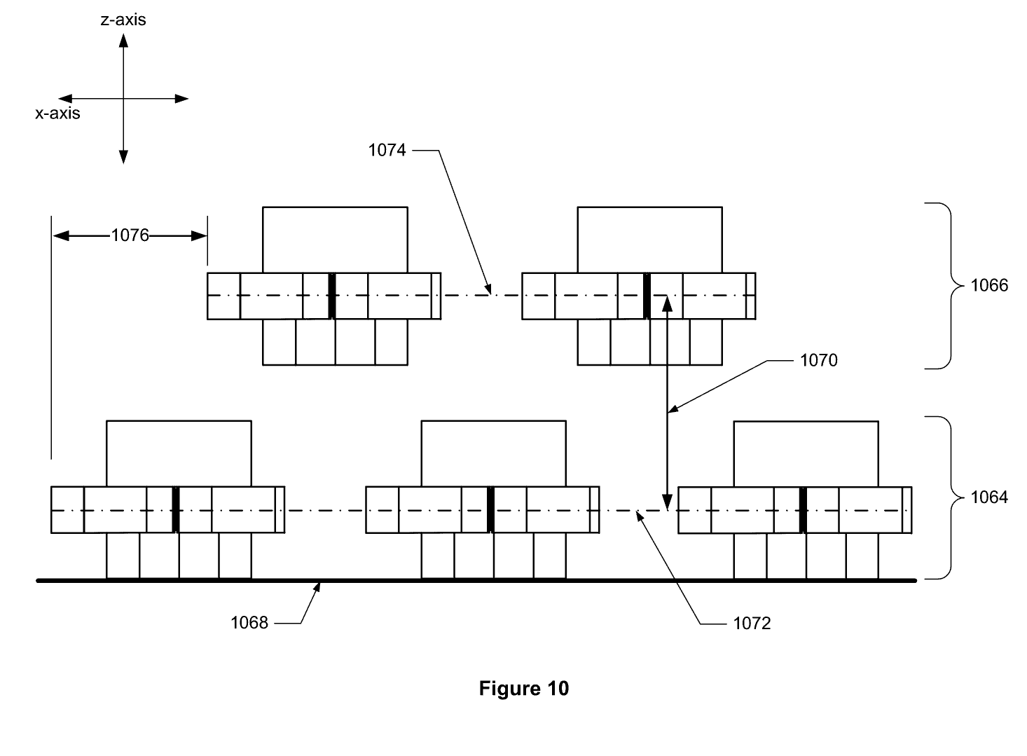

The second plurality of tools 1066 may also be offset horizontally, e.g., along the x-axis and/or y-axis, from the first plurality of tools 1064, as can be seen, for instance, in FIG. 10. In some implementations, the second plurality of tools 1066 may be horizontally offset from the first plurality of tools 1064 by a first horizontal distance 1076. As seen in FIG. 10, the horizontal offset may be a horizontal distance measured between an edge of one tool in the first plurality of tools 1064 and the edge of one tool in the second plurality of tools 1066. The horizontal offset may be configured such that all of the tools' one or more interfaces that may receive a container of wafers, i.e. the interfaces of both the first and second pluralities of tools, are not obstructed in the vertical, i.e., z-direction. This may enable all of the tools' one or more interfaces that may receive a container of wafers to be accessed by a single OHT system as seen in FIG. 11, discussed below.

FIG. 11 depicts top and rear views of an example dual level layout involving 16 tools. The tools in FIG. 11 include the exclusion zones which are shown as solid lines. The top portion of the FIG. 11 is the top view, i.e., viewed along the z-axis, while the lower portion is the rear view, i.e., viewed along the y-axis. The axis legend 1178 is for the top portion and the axis legend 1180 is for the bottom portion. The first average wafer transfer plane of the first plurality of tools may include the x-axis and the y-axis, with the y-axis normal to the x-axis, as seen in FIG. 11. The second average wafer transfer plane of the second plurality of tools may also include an x-axis and a y-axis, with the y-axis normal to the x-axis.

As can be seen in FIG. 11, similar to FIG. 10, a second plurality of eight tools 1166 is shown elevated above a first plurality of eight tools 1164, as well as horizontally offset from each other along the x-direction. The dual level layout, as seen from above in the top portion of FIG. 11, is arranged such that the interfaces that may receive a container of wafers in the second plurality of tools 1166 do not obstruct the interfaces that may receive a container of wafers in the first plurality of tools 1164. For instance, 1106B is an interface that may receive a container of wafers for a tool in the first plurality of tools 1164, 1106A is an interface that may receive a container of wafers for a tool in the second plurality of tools 1166, and such interfaces are unobstructed as seen from the top view, i.e., vertically along the z-axis.

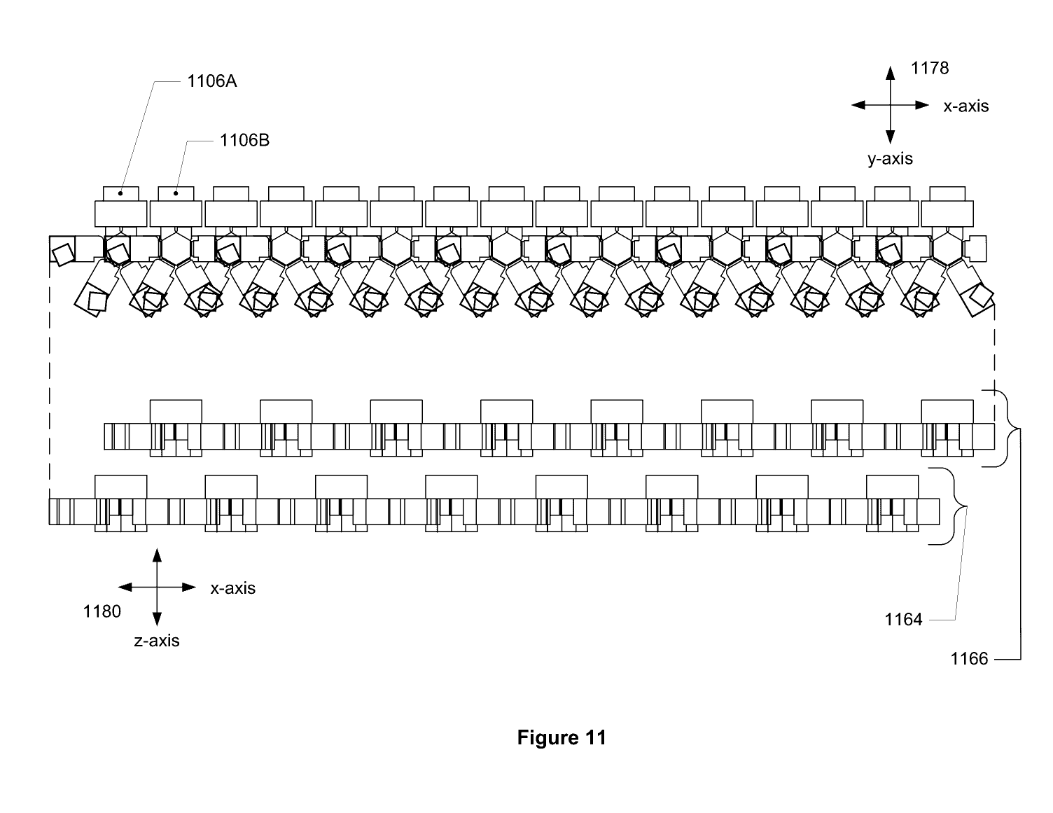

FIGS. 12 and 13 depict off-angle views of the example dual layout of FIG. 11. Similar to FIG. 11, the exclusion zones of the tools in both FIGS. 12 and 13 are shown as solid lines for demonstrative purposes.

Moreover, in some embodiments, the second plurality of tools may be arranged such that some area(s) of one or more tools in the second plurality of tools overlaps with the first plurality of tools, for example when viewed from the top along the z-axis like that in FIG. 11. For instance, some process chambers of the second plurality of tools may vertically overlap with one or more process chambers of the first plurality of tools. In some embodiments, the first plurality of tools may be arranged such that there is no such overlap.

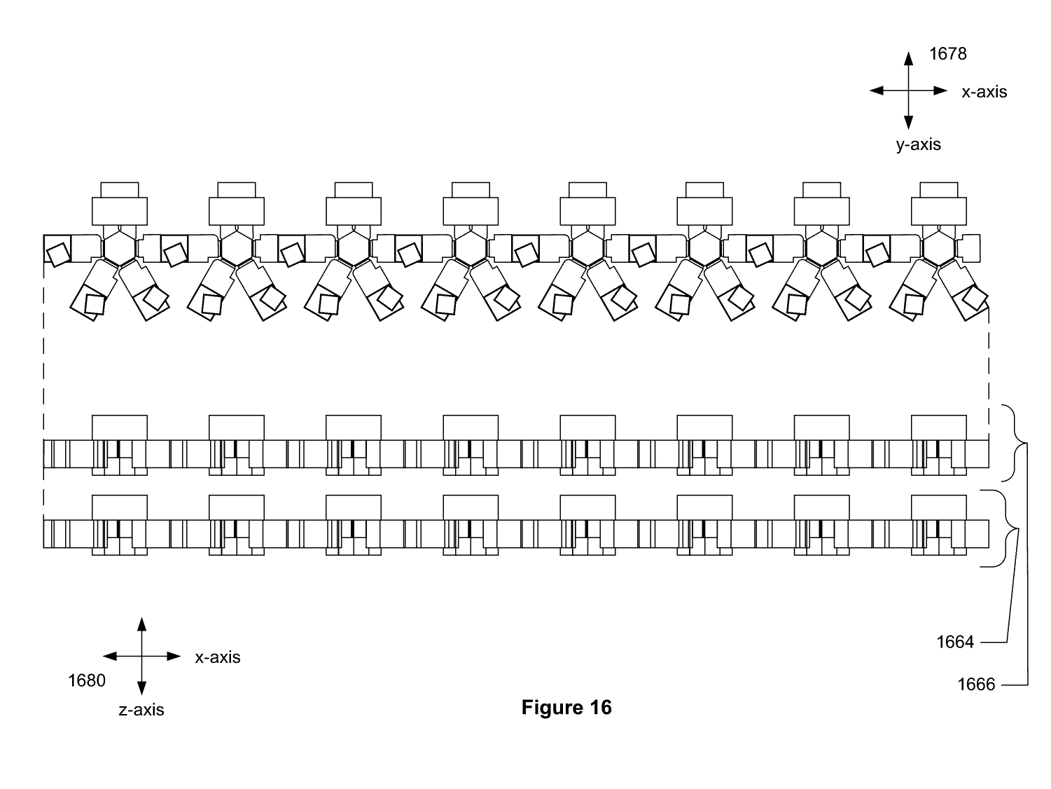

As state above, the horizontal offset of the second plurality of tools may be in a direction along the x-axis (as seen in FIGS. 10 and 11), the y-axis, or both the x- and y-axis. For example, FIG. 17 depicts a top view of another example dual level layout involving 16 tools. Here, the view is normal to the z-axis like in FIG. 11, but a second plurality of semiconductor processing tools 1766 can be seen offset from the first plurality of semiconductor processing tools by a second horizontal distance 1775 along the y-axis, in addition to offset by the first horizontal distance like in FIG. 10 (not labeled).

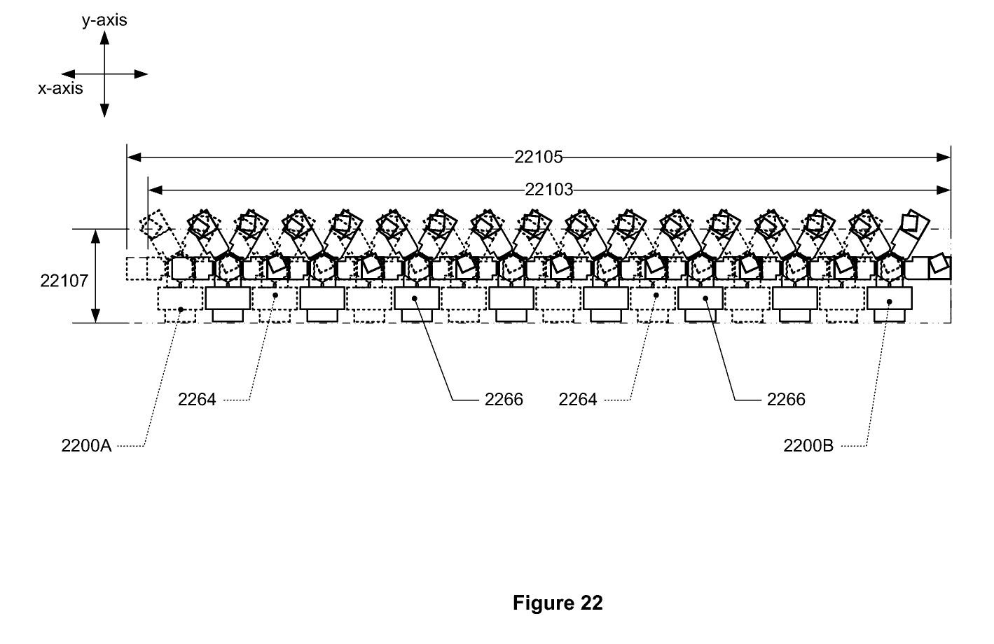

FIG. 22 depicts a top view of the example dual level layout similar to that of FIG. 11. Here, a first plurality of tools 2264 is identified in dotted lines and is below (along the z-axis) a second plurality of tools 2266 that is vertically offset above the first plurality of tools 2264. Like above, the first plurality of tools 2264 may be considered adjacent to, i.e., substantially on, the Fab floor. Similar to the measurements described above in FIGS. 20, 21, 8, and 9, the first length of these two pluralities of tools 2264 and 2266 may be considered the distance between an outer edge of a physical component of one of the tools on an end of the plurality of tools 2264 that is adjacent to the Fab floor, such as tool 2200A seen on the left hand side of FIG. 22, and an outer edge of an exclusion zone of a tool in the elevated plurality of tools 2266 that is on the opposite end of the plurality of tools 2264 (e.g., farthest from tool 2200A), such seen in the right hand side of FIG. 22. A second length 22105 may be considered the distance between an outer edge of an exclusion zone of one of the tools on an end of the plurality of tools 2264 located on the Fab floor, such as tool 2200A seen on left hand side of FIG. 21, and an outer edge of an exclusion zone of a tool in the elevated plurality of tools 2266 that is on the opposite end of the plurality of tools 2264 (e.g., farthest from tool 2200A), such seen in the right hand side of FIG. 22.

The total width 22107 of the two pluralities of tools may be measured between an outer edge of a physical component of one of the tools within one plurality of tools 2264 and an outer edge of a physical component of one of the tools within the other plurality of tools 2264, as seen in FIG. 22. The width 22107 may also be measured between a physical component of a tool and an edge of an exclusion zone. In some embodiments, the first length 22103 may be about 1,251.5 inches (e.g., about 31,789 millimeters), the second length 22105 may be about 1,287.5 inches (e.g., about 32,704 millimeters), and the width 22107 may be about 147.4 inches (e.g., about 3,752 millimeters).

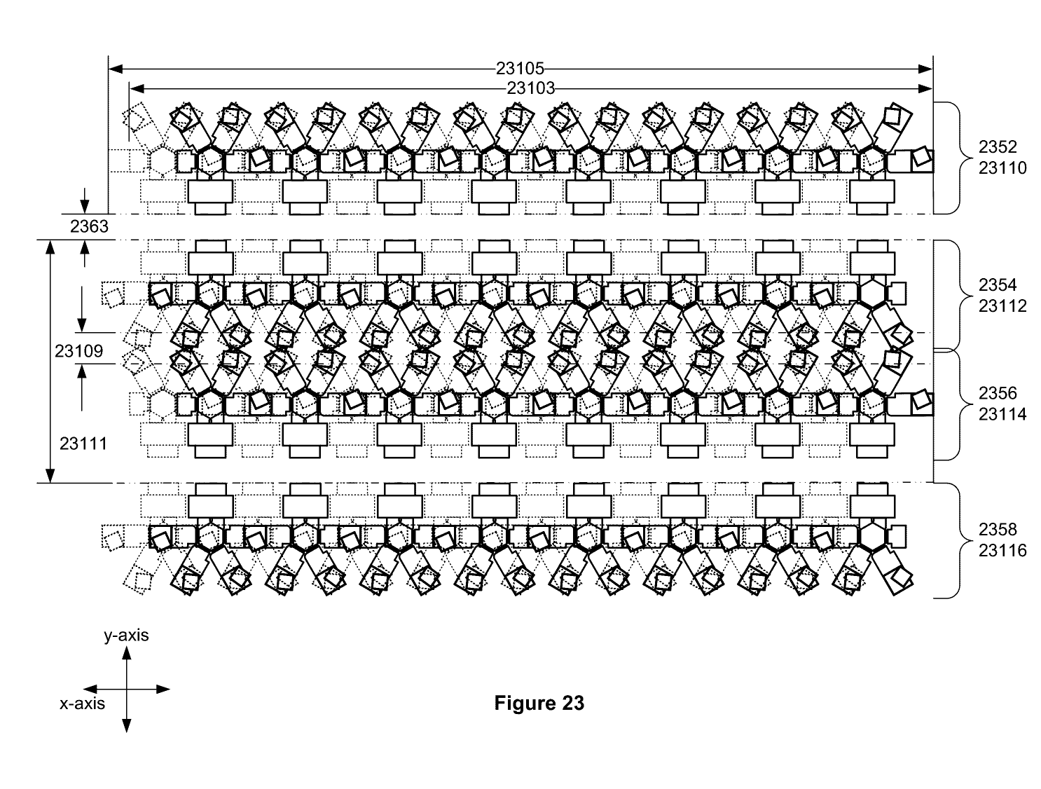

FIG. 23 depicts a top view of another example dual level layout on a Fab level. The layout includes eight pluralities of tools, with each plurality having eight tools thus resulting in a total of 64 tools. Four pluralities of tools, 2352, 2354, 2356, and 2358 are arranged similar to that of FIG. 9 and the tools within these four pluralities of tools may be considered adjacent to, e.g., substantially on, a Fab floor, like discussed above. For clarity purposes, these four pluralities of tools are shown in dotted lines. These four pluralities of tools may also be considered the “first plurality of tools” as discussed herein. Four additional pluralities of tools, 23110, 23112, 23114, and 23116 are also shown in FIG. 23 and may be considered pluralities of tools that are elevated, e.g., vertically offset from the other four pluralities of tools 2352, 2354, 2356, and 2358, respectively. The four pluralities of tools, 23110, 23112, 23114, and 23116 are identified with solid lines and may be considered the “second plurality of tools” as discussed herein.

In some embodiments, the layout depicted in FIG. 23 may be the same as that depicted in FIG. 9, but with a plurality of tools (e.g., the four pluralities of tools, 23110, 23112, 23114, and 23116) elevated above a first plurality of tools (e.g., 2352, 2354, 2356, and 2358).

The spacing between and dimensions of the tools and pluralities of tools in FIG. 23 may incorporate similar and/or identical spacing elements described above, such as with FIGS. 9 and 22. For example, a first length 23103 of pluralities of tools 2352 and 23110 may be the same as the first length 22103 of FIG. 22 and such discussion is incorporated herein with respect to FIG. 23. Likewise, a second length 23105 may be the same as the second length 22105 of FIG. 22 and such discussion is also incorporated herein with respect to FIG. 23. Here, however, first length 23103 may be about 1,251.5 inches (e.g., 31,789 millimeters) and the second length 23105 may be about 1,287.5 inches (e.g., 32,704 millimeters).

The separation distances between pluralities of tools, i.e., in the y-direction, may be the same as described above with respect to FIG. 9. For example, separation distance 2363 exists between the interfaces which may receive wafers of the tools between pluralities of tools 2352, 23110 and 2354, 2311 like described above with reference to separation distance 963 of FIG. 9 and such discussion is incorporated herein. Here, the separation distance 2363 may be about 55.0 inches (e.g., 1,397 millimeters). Additional spacing between other pluralities of tools, such as between adjacent pluralities of tools 2354, 23112 and 2356, 23114, e.g., spacing distance 23109, may be the same as spacing distance 8109 of FIG. 8 and 9109 of FIG. 9 and such discussion is incorporated herein. In some embodiments, spacing distance 23109 may be 41 inches (e.g., 1,041 millimeters). There may also be measured spacing between the two center pluralities of tools 2354, 23112, 2356, 23114 and adjacent pluralities of tools, such as pluralities of tools 2358 and 23116. This other separation distance 23111 may be the same as the other separation 9111 discussed above and is incorporated herein. In some embodiments, this other separation distance 23111 may be about 391.4 inches (e.g., 9,943 millimeters) or about 374.5 inches (e.g., 9,512 millimeters).

Although not shown herein, the layout of FIG. 8 may also have a plurality of tools elevated above it similar to that described in FIGS. 9 and 23.

In some embodiments, a plurality of sixteen tools (e.g., a “cell block” or “cell”) may be considered for spacing considerations of layouts of semiconductor processing tools within a Fab level. In some embodiments, a cell block may have eight tools across (e.g., a length) and a two rows of eight tools, totaling sixteen tools, such as that shown in FIGS. 21 and 9 (e.g., pluralities of tools 954 and 956, or 952 and 954). In some example layouts (e.g., a “standard layout” like that in FIG. 9), a length of the eight tools (e.g., 9103 or 9105 of FIG. 9) may be about 29.9 meters, may have a width (e.g., distance 9111 of FIG. 9) of about 9.94 meters or about 9.51 meters, an area of about 297 m² or about 284 m² (e.g., in the x-y axes of FIG. 9), sixteen tools per cell, and an area used per tool of about 18.6 m² or about 17.8 m² (e.g., in the x-y axes of FIG. 9). In another example layout (e.g., an “in line” layout like in FIG. 8, such as pluralities of tools 852 and 854, and FIG. 22), a length of the eight tools (e.g., 8103 or 8105 of FIGS. 8, 21103 and 21105 of FIG. 21) may be about 31.7 meters, may have a width (e.g., distance 8107 of FIG. 8 and 21107 of FIG. 21) of about 8.17, an area of about 259 m² (e.g., in the x-y axes of FIG. 8), sixteen tools per cell, and an area used per tool of about 15. m² or about 17.8 m² (e.g., in the x-y axes of FIG. 9).

An example dual level layout, such as shown in FIG. 23 (e.g., a block involving pluralities of tools 2354, 23112, 2356, and 23114) and discussed above, may have a length of the eight tools (e.g., 23103 or 23105 of FIG. 23) of about 29.9 meters, a width (e.g., distance 23111 of FIG. 23) of about 9.94 meters, an area of about 297 m² (e.g., in the x-y axes of FIG. 23), 32 tools per cell, and an area used per tool of about 9.3 m² or about 17.8 m² (e.g., in the x-y axes of FIG. 9). Accordingly, the dual level layout is able to have double the number of tools (32 versus 16) using the same or similar area as convention layouts (297 m² for both the standard and dual level layouts).

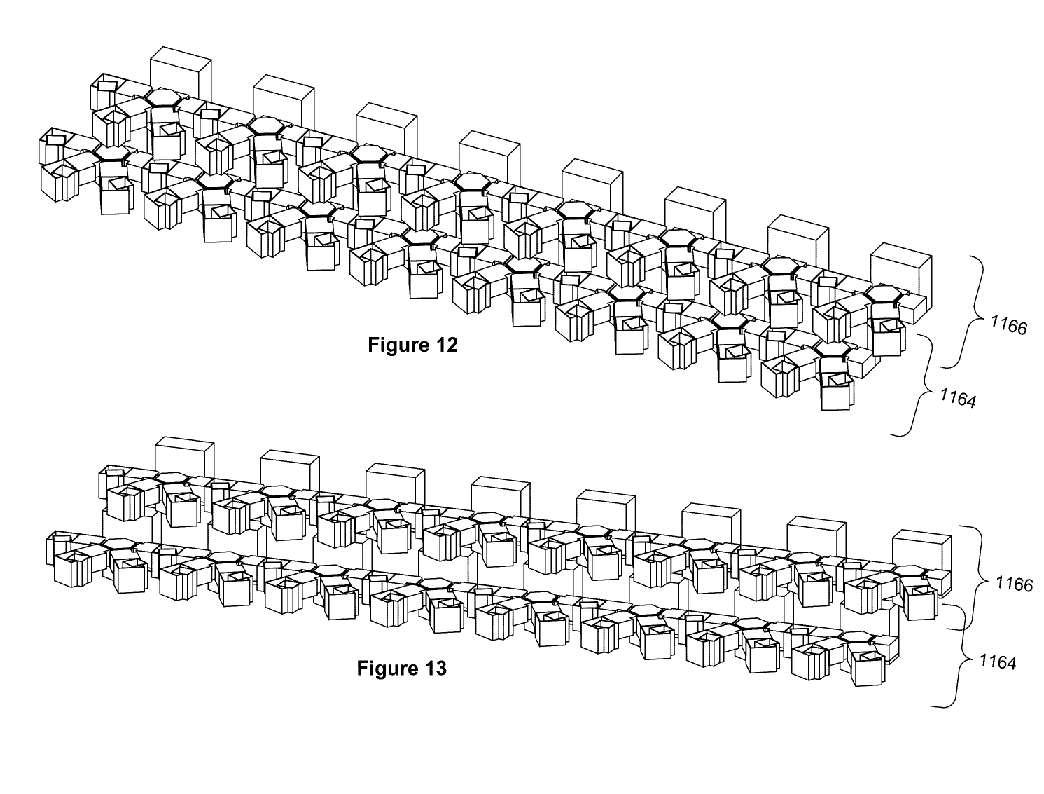

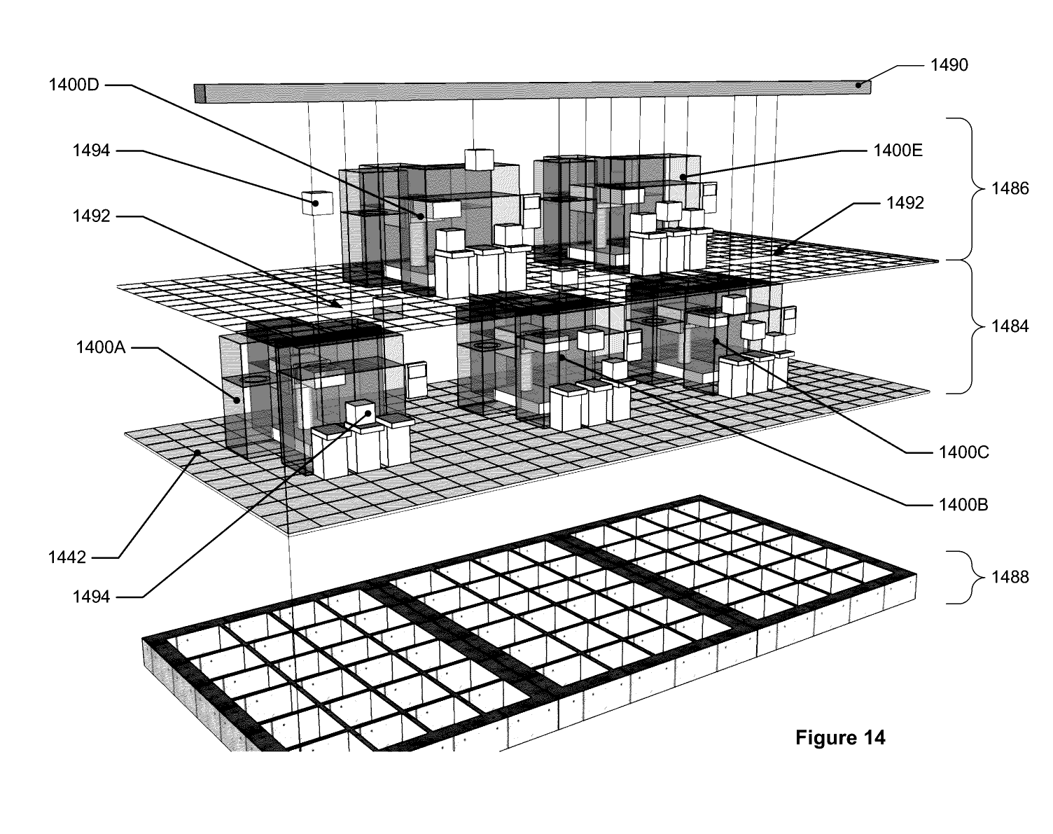

Another example of such a dual level layout embodiment, i.e. in which the second plurality of tools are elevated above and horizontally offset from the first plurality of tools, can be seen in FIGS. 14 and 15. FIG. 14 depicts an isometric view of a partially exploded, partial dual layout of semiconductor processing tools in an example Fab while FIG. 15 depicts a front view of the partially exploded, partial dual layout of semiconductor processing tools in the example Fab of FIG. 14. The Fab Cleanroom of FIG. 14 (which is some embodiments may be a non-cleanroom environment) includes a Fab Level floor 1442, a first tool level 1484, a second tool level 1486 (e.g., an intermediate tool level, an intermediate level, or an intermediate fabrication level), a Sub Fab Level 1488, and an overhead transport system (“OHT”) 1490. As can be seen in FIG. 14, there are three semiconductor processing tools 1400A, 14006, 1400C arranged adjacent to, e.g. substantially on, the Fab Level floor 1442 (this may be considered a first plurality of tools 1464) and in the first tool level 1484; and there are two semiconductor processing tools 1400D and 1400E elevated above, e.g., vertically offset, from the first plurality of tools (this may be considered a second plurality of tools 1466) in the second tool level 1486. These features and aspects of FIG. 14 are also depicted in FIG. 15.

As can be seen in FIGS. 14 and 15, the structure on which the second plurality of tools is placed does not obstruct the vertical access to at least some parts of the first plurality of tools, including the interface which may receive a container of wafers. In such examples, as well as some other embodiments of the dual level layout, the OHT system may be shared between the first plurality of tools and the second plurality of tools, and the structure that elevates the second plurality of tools may be configured to allow the OHT system to access both the first and the second pluralities of tools.

For instance, the example Fab Cleanroom of FIGS. 14 and 15 is configured such that the single OHT 1490 may access all of the tools in the example Fab Cleanroom, including those on the first tool level 1484 and the second tool level 1486. Similar to the above discussion, such configurations may include the second plurality of tools 1466 on the second tool level 1486, i.e., those tools that are vertically above the first plurality of tools 1464 on the Fab Level floor 1442, being horizontally offset from the first plurality of tools 1464. The configuration also may include the structure that supports the second plurality of tools 1466 on the second tool level 1486, such as a floor as shown in FIG. 14, being configured to enable the OHT to transport items, such as containers storing wafers, to both pluralities of tools. For instance, as seen in FIGS. 14 and 15, the floor of the second tool level 1486 has three access ports 1492 which enable containers storing wafers 1494, to be transported to the first plurality of tools 1464 (e.g., tools 1400A-C on the Fab Level floor 1442 on the first tool level 1484) through the access ports 1492 and to the second plurality of tools 1466 (e.g., 1400D and 1400E on the second tool level 1486). In some embodiments, the structure supporting the second plurality of tools may not be a floor and in such instances, the structure may be placed, arranged, constructed and/or configured to also enable the OHT to access both the first plurality of tools on the Fab Level floor and the second plurality of tools offset above the first plurality of tools.

The Fab Cleanroom depicted in FIGS. 14 and 15 may include some or all of the aspects of a cleanroom discussed above, such as the Sub Fab Level 1488 including pumps, power, chillers, or other aspects used in semiconductor processing. Again, the concepts described herein, e.g., with respect to FIGS. 14 and 15, are applicable to a non-cleanroom environment.

It is also contemplated by the inventors that the multi-level layouts disclosed herein (including the dual level layout) may be configured such that the first plurality of tools (e.g., those located on the Fab Level floor) and the second plurality of tools (e.g., those vertically offset above the first plurality of tools) share facilities with each other. Some of these facilities may include, among other things, storage and/or packaging for a gas box, a water manifold, a pneumatic manifold, a high-voltage radiofrequency generator, pipes, wires, cables, tubes, conduit, a pump, a power box, a chiller, and an abatement consolidation. For example, one or more tools in the first plurality of tools may share a gas box with one or more tools in the second plurality of tools.

Additionally, it is contemplated by the inventors that the multi-level layouts disclosed herein (including the dual level layout) may be implemented within a common cleanroom environment (e.g., a “commonly shared space”), which may include within a single Fab Level, a split Fab Level (e.g., two Fab levels), a semiconductor fabrication room of a building, and/or a single cleanroom environment with multiple levels, such as that depicted in FIGS. 14 and 15. As described above, FIGS. 14 and 15, for example, depict two pluralities of tools in a commonly shared space environment that includes a Fab level floor and a second floor that supports and elevates the second plurality of tools above the first plurality of tools. In such an environment, the dual level layout may be implemented in an environment in which the first and second pluralities of tools share a lighting system, OHT system, other cassette transfer system (e.g. robot arms), air system, and/or space. In some such embodiments, the common cleanroom environment may be a commonly shared space. It is also contemplated that in some other embodiments, the system may be implemented in a non-cleanroom environment in which the first and second pluralities of tools share a lighting system, OHT system, other cassette transfer system (e.g. robot arms), air system, and/or space. It is further contemplated that the dual level system may be implemented in a single room or environment that is partially defined vertically by a ceiling and a floor, and/or a partial ceiling/floor. It is further contemplated that one or more building floors may not be between the first plurality of semiconductor processing tools and the second plurality of semiconductor processing tools.

The multi-level layout may be utilized for tools that operate in a vacuum environment that is below atmospheric pressure, as well as for tools may operate at atmospheric pressure. The multi-level layout may also be utilized for embodiments containing all the same tools, similar tools, tools running different processes, and/or different tools. For instance, the first plurality of tools may include all identical tools, while the second plurality of tools may include one or more tools that are different than the tools in the first plurality of tools. Additionally, the first and second pluralities of tools may include the same or substantially the same tool.

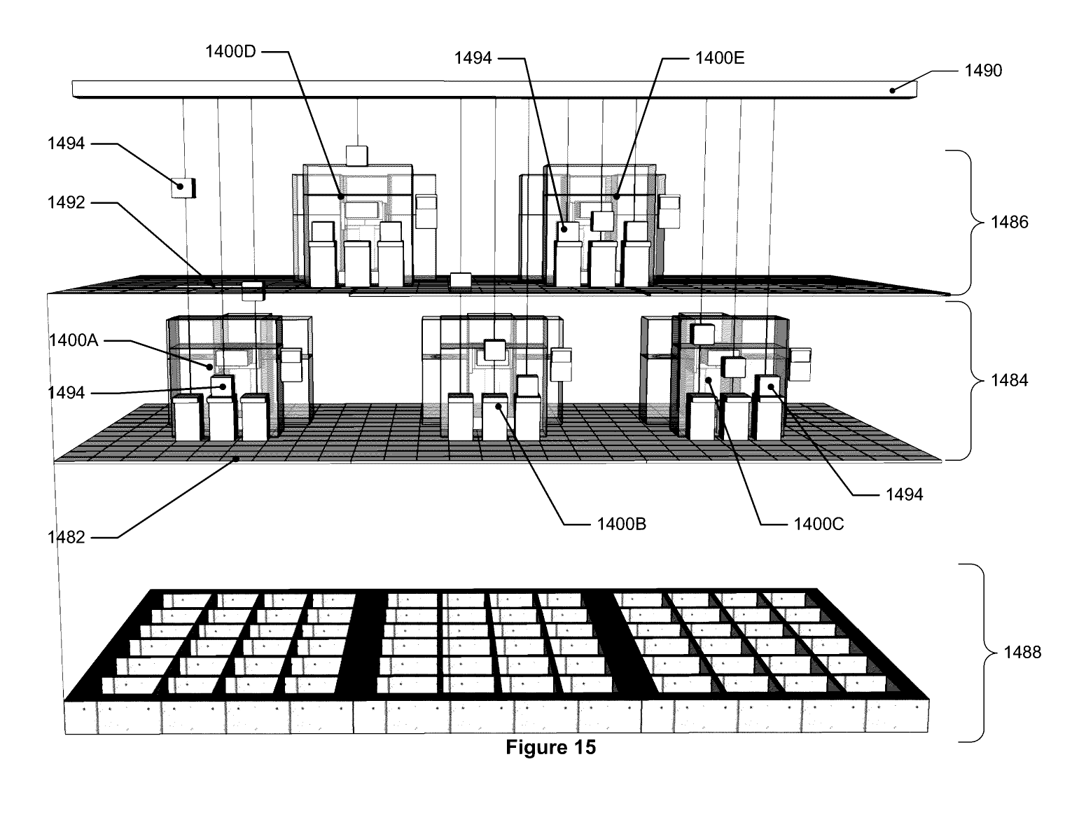

In some embodiments, there may be no horizontal offset between the first and second pluralities of tools; in some such configurations, the second plurality of tools may be substantially overlapping the first plurality of tools when viewed along a vertical direction, e.g., along the z-axis. FIG. 16 depicts top and rear views of another example dual level layout involving 16 tools. The tools in FIG. 16 include the exclusion zones which are shown as solid lines. The top portion of the FIG. 16 is the top view, i.e., viewed along the z-axis, while the lower portion is the rear view, i.e., viewed along the y-axis. The axis legend 1678 is for the top portion and the axis legend 1680 is for the bottom portion. As can be seen, similar to FIG. 11, a second plurality of eight tools 1666 is shown elevated above a first plurality of eight tools 1664, but these pluralities of tools are not horizontally and/or laterally offset from each other. When viewed from above, in the top portion of FIG. 16, it can be seen that the second plurality of tools 1666 substantially overlaps the first plurality of tools 1664 such that there is substantially no horizontal offset between the pluralities of tools in the x-direction or the y-direction. In some such embodiments, the footprint of the second plurality of tools 1666 may substantially overlap and/or match the footprint of first plurality of tools 1664. Similar to FIG. 11, the tools in FIG. 16 include the exclusion zones which are shown as solid lines.

The second plurality of tools may be elevated by one or more components secured to a portion, or part, of the Fab cleanroom and/or building, e.g. tool mounting architecture. In some embodiments, the second plurality of tools may be elevated by tool mounting architecture that includes a floor, or partial floor, that divides some or all of the Fab Level, but is still within the same cleanroom and/or shared environment as the first plurality of tools. In some such embodiments, the first and second pluralities of tools may share a common air supply system, and/or an OHT system. In some embodiments, the tool mounting architecture may be a support system that is secured to one or more walls of the Fab Level and that supports the second plurality of tools. The tool mounting architecture may also include a framework and/or catwalk that may be supported by the floor, the walls, and/or the ceiling of the Fab cleanroom and/or Fab Level.

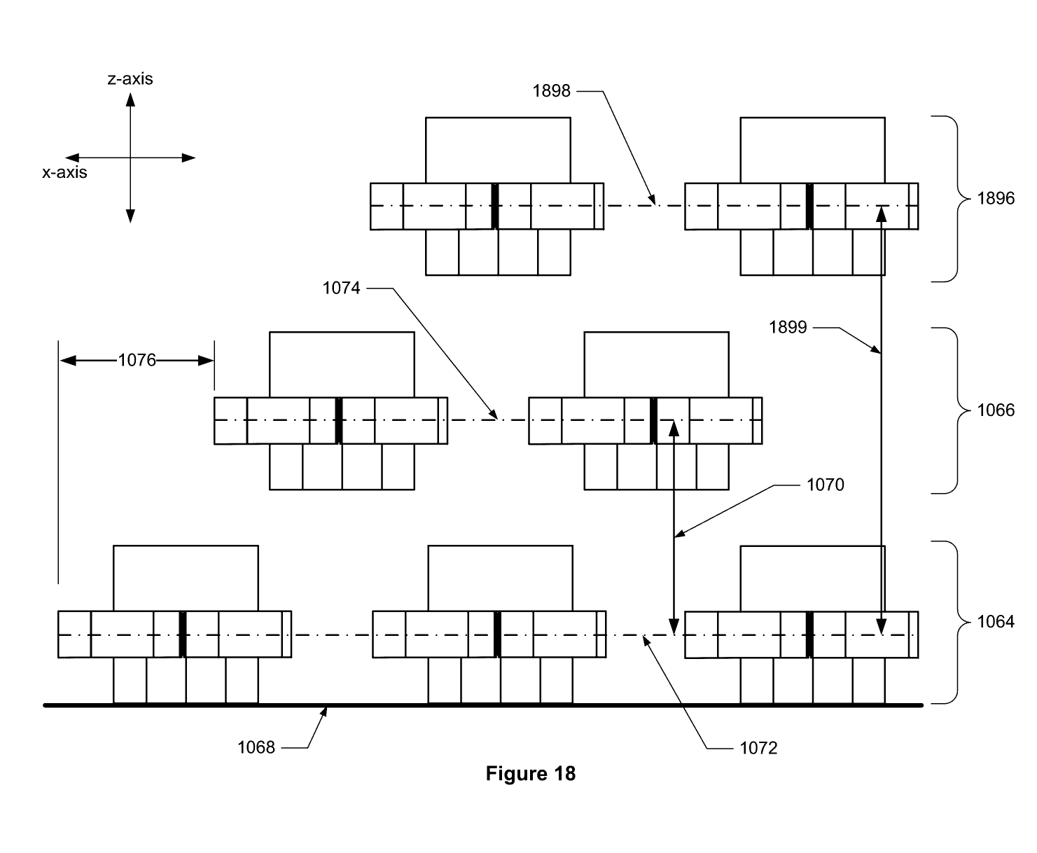

FIG. 19 depicts an off-angle view of an example structure supporting a semiconductor processing tool. As can be seen, a semiconductor processing tool 1900C is elevated above two other semiconductor processing tools 1900A and 1900B and the semiconductor processing tool 1900C is supported by a structure 19102 which is depicted as a platform. This platform 19102 may be supported from the ceiling, the wall, and/or the floor of the Fab level (not depicted).

The structure that elevates the second plurality of tools, e.g., the tool mounting architecture, may provide access to one or more of the tools within the second plurality of tools. Such access may be gained by a catwalk, platform, floor, and/or ladder. In some embodiments, the structure that elevates the second plurality of tools may not provide any access to the second plurality of tools (e.g., cables or a suspension system). In some embodiments, access may be gained to the second plurality of tools by a hoist system, suspension system, ladders, scaffolding, mechanical means (e.g. forklift, scissor lift, robot arm, crane), and/or another type of access system.

In some embodiments, the second plurality of tools may be elevated by tool mounting architecture that is a modular system. In some such embodiments, this modular system architecture may be installed at any desired level and/or location within the Fab Level. The modular system may function as a modular building block or modular system, which may be similar to scaffolding and/or racking.

In addition to the above discussion and the examples shown in the documents filed with this application, the multi-level layout may be implemented in various configurations. In some multi-level configurations, a common processing environment, e.g. a common cleanroom and/or Fab cleanroom, may include a first plurality of tools and a second plurality of tools, with the second plurality of tools vertically offset from the first plurality of tools by a distance as measured between the average wafer transfer plane of the first plurality of tools and the average wafer transfer plane of the second plurality of tools. The first plurality of tools may also be horizontally offset from the second plurality of tools by a horizontal distance. In some such configurations, the horizontal offset may permit some lateral overlap between the first and second pluralities of tools.

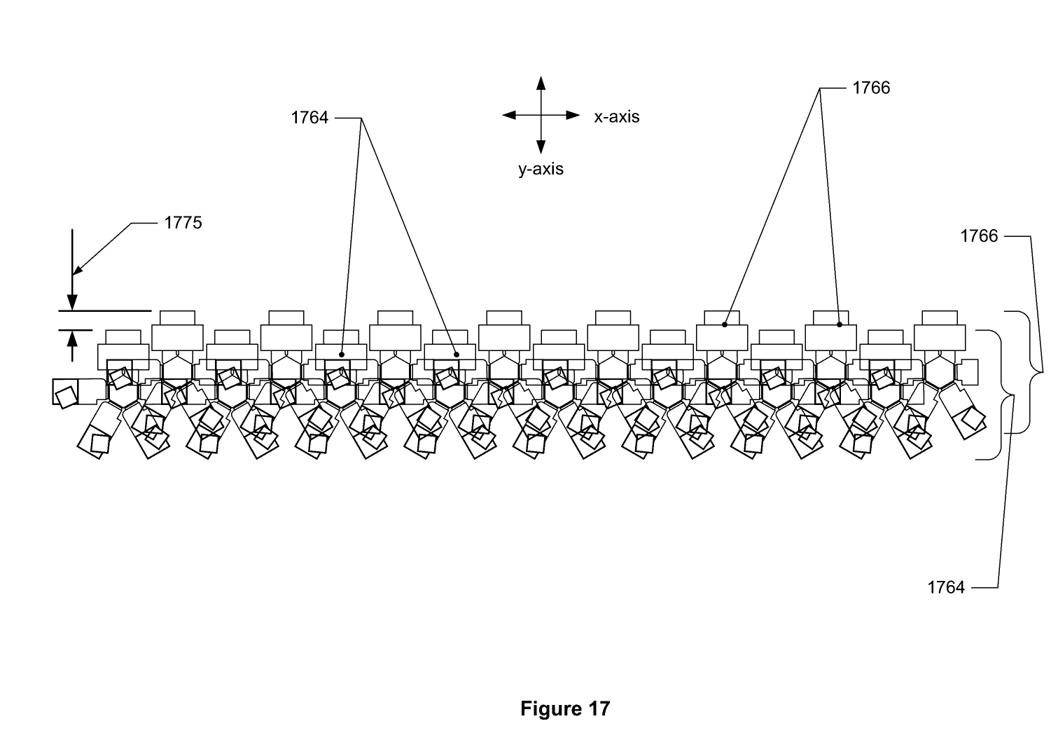

As noted above, the present disclosure includes more than one plurality of tools elevated above a first plurality of tools that are arranged adjacent to a Fab level floor. FIG. 18 depicts a rear view of a representational example of two pluralities of tools elevated above a plurality of tools located adjacent to, e.g., substantially on, a Fab Level floor. This Figure is similar to FIG. 10 except that a third plurality of semiconductor processing tools 1896 can be seen elevated above the first and the second pluralities of tools, 1064 and 1066, respectively, and including a third average wafer transfer plane 1898. The third plurality of semiconductor processing tools 1896 are vertically offset from the first plurality of semiconductor processing tools 1064 by a second vertical distance 1899 measured between the third average wafer transfer plane 1898 and the first average wafer transfer plane 1072. This third plurality of tools 1896 may be configured and located similarly to the second plurality of tools as discussed above and such discussion is incorporated herein, such as the horizontal offset between the third plurality of tools and the first plurality of tools (e.g., in a direction along the x-axis, y-axis, or both the x- and y-axes), as well as the overlap of the third plurality of tools and the first plurality of tools when viewed along the z-axis.

Unless the context of this disclosure clearly requires otherwise, throughout the description and the embodiments, the words “comprise,” “comprising,” and the like are to be construed in an inclusive sense as opposed to an exclusive or exhaustive sense; that is to say, in a sense of “including, but not limited to.” Words using the singular or plural number also generally include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list, and any combination of the items in the list. The term “implementation” refers to implementations of techniques and methods described herein, as well as to physical objects that embody the structures and/or incorporate the techniques and/or methods described herein.

1. A semiconductor processing system, comprising:
a first plurality of semiconductor processing tools with a first average wafer transfer plane, and
a second plurality of semiconductor processing tools with a second average wafer transfer plane, wherein:
the second plurality of semiconductor processing tools is vertically offset from the first plurality of semiconductor processing tools by a first vertical distance measured between the first average wafer transfer plane and the second average wafer transfer plane, and
the first plurality of semiconductor processing tools and the second plurality of semiconductor tools are in a commonly shared space.

2. The system of claim 1, wherein one or more building floors may not be between the first plurality of semiconductor processing tools and the second plurality of semiconductor processing tools.

3. The system of claim 1, wherein the commonly shared space is a cleanroom.

4. The system of claim 1, wherein the commonly shared space is a semiconductor fabrication room of a building.

5. The system of claim 1, further comprising a tool mounting architecture, wherein the second plurality of semiconductor processing tools are mounted in engagement with the tool mounting architecture.

6. The system of claim 5, wherein the tool mounting architecture is one or more of: a suspension system, a floor, a wall, a ceiling, a frame, a catwalk, and a modular system.

7. The system of claim 1, wherein the first vertical distance is less than about fifty feet.

8. The system of claim 1, wherein the second plurality of semiconductor processing tools at least partially overlaps the first plurality of semiconductor processing tools when viewed at a direction normal to the second average wafer transfer plane.

9. The system of claim 8, wherein:
the first average wafer transfer plane includes an x-axis and a y-axis normal to the x-axis, and
the second plurality of semiconductor processing tools is offset from the first plurality of semiconductor processing tools in a direction along of one or more of: the x-axis and the y-axis.

10. The system of claim 9, wherein the second plurality of semiconductor processing tools is offset from the first plurality of semiconductor processing tools by a first horizontal distance along the x-axis.

11. The system of claim 9, wherein the second plurality of semiconductor processing tools is offset from the first plurality of semiconductor processing tools by a second horizontal distance along the y-axis.

12. The system of claim 1, further comprising a fabrication level with a floor wherein the first plurality of semiconductor processing tools is arranged adjacent to the floor.

13. The system of claim 12, further comprising an overhead hoist transportation system, wherein:
each semiconductor processing tool includes one or more interfaces that receives a container of wafers, and
the first plurality of semiconductor processing tools and second plurality of semiconductor processing tools are arranged such that the overhead hoist transportation system can access the one or more interfaces that receives a container of wafers of the first plurality of semiconductor processing tools and the one or more interfaces that receives a container of wafers of second plurality of semiconductor processing tools.

14. The system of claim 12, further comprising an intermediate fabrication level wherein the second plurality of semiconductor processing tools is arranged in the intermediate fabrication level.

15. The system of claim 12, further comprising a sub-fabrication level adjacent to the fabrication level, wherein one or more of the following are at least partially located in the sub-fabrication level: storage and/or packaging for a gas box, a water manifold, a pneumatic manifold, or a high-voltage radiofrequency generator.

16. The system of claim 1, further comprising an air system wherein the air system provides filtered air to the first plurality of semiconductor processing tools and the second plurality of semiconductor processing tools.

17. The system of claim 1, further comprising a third plurality of semiconductor processing tools with a third average wafer transfer plane, wherein the third plurality of semiconductor processing tools are vertically offset from the first plurality of semiconductor processing tools by a second vertical distance measured between the third average wafer transfer plane and the first average wafer transfer plane.

18. The system of claim 1, wherein:
each semiconductor processing tool has one or more exclusion zones adjacent to the perimeter of that semiconductor processing tool,
one or more of the exclusion zones of one semiconductor processing tool is able to overlap with one or more exclusion zones of another other semiconductor processing tools, and
the first plurality of semiconductor processing tools and the second plurality of semiconductor processing tools are arranged such that during normal semiconductor processing operations the perimeter of at least one semiconductor processing tool does not encroach the one or more exclusion zones of at least one other semiconductor processing tool.

19. The system of claim 1, further comprising semiconductor processing facilities, wherein:
semiconductor processing facilities include one or more of: storage and/or packaging for a gas box, a water manifold, a pneumatic manifold, a high-voltage radiofrequency generator, pipes, wires, cables, tubes, conduit, a pump, a power box, a chiller, and an abatement consolidation, and
at least one of the semiconductor processing tools in the first plurality of semiconductor processing tools shares one or more of the semiconductor processing facilities with at least one of the semiconductor processing tools from the second plurality of semiconductor processing tools.

20. A semiconductor processing system, comprising:
a plurality of semiconductor processing tools, each of the plurality of semiconductor processing tools having a horizontal extent and an average wafer transfer plane; and
a tool mounting architecture in a commonly shared space, wherein:
the plurality of tools are mounted such that the horizontal extent of a first of the plurality of mounted tools overlaps the horizontal extent of a second of the plurality of mounted tools, and the average wafer transfer plane of the first of the plurality of mounted tools is vertically offset from a second average wafer transfer plane of the second of the plurality of mounted tools.
